(19) United States
(12) Patent Application Publication
(10) Pub. No.: US 2026/0026242 A1
(43) Pub. Date: Jan. 22, 2026

(54) DISPLAY PANEL, ELECTRONIC DEVICE, AND METHOD OF MANUFACTURING THE DISPLAY PANEL

(71) Applicant: Samsung Display Co., LTD., Yongin-si (KR)

(72) Inventors: SANGJIN PARK, Yongin-si (KR); YOUNGSEOK BAEK, Yongin-si (KR); Hee Jun YANG, Yongin-si (KR); JINHO HWANG, Yongin-si (KR)

(21) Appl. No.: 19/169,360

(22) Filed: Apr. 3, 2025

(30) Foreign Application Priority Data
Jul. 17, 2024 (KR) 10-2024-0094378

(51) Int. Cl. H10K 59/80; H10K 59/12; H10K 59/122

(52) U.S. Cl. CPC H10K 59/873; H10K 59/1201; H10K 59/122

(57) ABSTRACT

A display panel includes a base layer, a pixel definition layer disposed on the base layer and having a light emitting opening, a barrier wall disposed on the pixel definition layer and having a barrier wall opening, a light emitting element disposed in the light emitting opening and the barrier wall opening and including an anode, a light emitting pattern, and a cathode that is in contact with the barrier wall, a lower encapsulation inorganic pattern including a first portion disposed in the barrier wall opening and covering the light emitting element, a second portion extending from the first portion in a thickness direction of the base layer, and a third portion extending from the second portion and spaced apart from an upper surface of the barrier wall, and a common inorganic layer covering a side surface of the third portion of the lower encapsulation inorganic pattern.

This application claims priority to Korean Patent Application No. 10-2024-0094378, filed on Jul. 17, 2024, and all the benefits accruing therefrom under 35 U.S.C. § 119, the content of which in its entirety is herein incorporated by reference.

### BACKGROUND

### 1. Field

The present disclosure relates to a display panel, an electronic device, and a method of manufacturing the display panel. More particularly, the present disclosure relates to a display panel with improved display quality, an electronic device, and a method of manufacturing the display panel.

### 2. Description of Related Art

Electronic devices such as, for example, televisions, monitors, smartphones, and tablet computers, include a display panel to provide and display images to a user. Various display panels, such as, for example, a liquid crystal display panel, an organic light emitting display panel, an electrowetting display panel, and an electrophoretic display panel, are being developed as the display panel.

A organic light emitting display panel may include an anode, a cathode, and a light emitting pattern. The light emitting pattern is provided in each light emitting area, and the cathode provides a common voltage to each light emitting area.

### SUMMARY

The present disclosure provides a display panel with improved display quality.

The present disclosure provides an electronic device including the display panel.

The present disclosure provides a method of manufacturing the display panel.

Embodiments of the inventive concept provide a display panel including a base layer, a pixel definition layer disposed on the base layer, wherein a light emitting opening is defined in the pixel definition layer, a barrier wall disposed on the pixel definition layer, wherein a barrier wall opening defined in the barrier wall overlaps the light emitting opening, a light emitting element disposed in the light emitting opening and the barrier wall opening and including an anode, a light emitting pattern, and a cathode that is in contact with the barrier wall, a lower encapsulation inorganic pattern including a first portion disposed in the barrier wall opening and covering the light emitting element, a second portion extending from the first portion in a thickness direction of the base layer, and a third portion extending from the second portion and spaced apart from an upper surface of the barrier wall when viewed in a cross-section, and a common inorganic layer covering a side surface of the third portion of the lower encapsulation inorganic pattern.

The upper surface of the barrier wall, the second portion of the lower encapsulation inorganic pattern, the third portion of the lower encapsulation inorganic pattern, and the common inorganic layer define a separation area.

The separation area surrounds the second portion of the lower encapsulation inorganic pattern when viewed in a plane.

The display panel further includes an encapsulation organic layer that covers the lower encapsulation inorganic pattern and the common inorganic layer, and the encapsulation organic layer is directly in contact with an upper surface of the lower encapsulation inorganic pattern.

The separation area is spaced apart from the encapsulation organic layer.

The display panel further includes an additional encapsulation inorganic pattern disposed between the lower encapsulation inorganic pattern and the encapsulation organic layer.

The lower encapsulation inorganic pattern has an undercut shape with respect to the additional encapsulation inorganic pattern, and the additional encapsulation inorganic pattern includes a tip portion that protrudes more than the lower encapsulation inorganic pattern.

The common inorganic layer is in contact with a lower surface of the additional encapsulation inorganic pattern defining the tip portion.

A side surface of the lower encapsulation inorganic pattern is aligned with a side surface of the additional encapsulation inorganic pattern.

The common inorganic layer is in contact with the side surface of the lower encapsulation inorganic pattern and the side surface of the additional encapsulation inorganic pattern.

The common inorganic layer includes an inorganic material.

The common inorganic layer includes at least one of silicon oxide (SiOₓ), silicon nitride (SiNₓ), and silicon oxynitride (SiON).

Embodiments of the inventive concept provide a method of manufacturing a display panel. The method includes providing a preliminary display panel including a base layer, a pixel definition layer disposed on the base layer, and a preliminary barrier wall disposed on the pixel definition layer, forming a barrier wall from the preliminary barrier wall, wherein a barrier wall opening is defined in the barrier wall, etching the pixel definition layer, wherein etching the pixel definition layer forms a light emitting opening overlapping the barrier wall opening, forming a light emitting element including an anode, a light emitting pattern, and a cathode in the light emitting opening and the barrier wall opening, forming a lower encapsulation inorganic pattern covering the light emitting element, depositing a preliminary common inorganic layer covering the lower encapsulation inorganic pattern, and etching a portion of the preliminary common inorganic layer, which overlaps the barrier wall opening, wherein etching the portion of the preliminary common inorganic layer forms a common inorganic layer covering a side surface of the lower encapsulation inorganic pattern.

The forming of the light emitting element includes forming a dummy layer including the same material as the light emitting pattern and the cathode on the barrier wall. The forming of the lower encapsulation inorganic pattern covering the light emitting element includes depositing a lower encapsulation inorganic layer covering an inner portion of the barrier wall opening and an upper portion of the barrier wall, removing a portion of the lower encapsulation inorganic layer, wherein the portion of the lower encapsulation inorganic layer does not overlap the light emitting element, and removing the dummy layer.

The depositing of the preliminary common inorganic layer includes forming a separation area based on the barrier wall, the lower encapsulation inorganic pattern, and the preliminary common inorganic layer.

The method further includes forming an encapsulation organic layer that covers the lower encapsulation inorganic pattern and the common inorganic layer, and the encapsulation organic layer is directly in contact with an upper surface of the lower encapsulation inorganic pattern.

The method further includes forming an additional encapsulation inorganic pattern on the lower encapsulation inorganic pattern, and the additional encapsulation inorganic pattern includes a tip portion that protrudes more than the lower encapsulation inorganic pattern, and the common inorganic layer is in contact with a lower surface of the additional encapsulation inorganic pattern that defines the tip portion.

The method further includes forming an additional encapsulation inorganic pattern on the lower encapsulation inorganic pattern, the side surface of the lower encapsulation inorganic pattern is aligned with a side surface of the additional encapsulation inorganic pattern, and the common inorganic layer is in contact with the side surface of the lower encapsulation inorganic pattern and the side surface of the additional encapsulation inorganic pattern.

The forming of the common inorganic layer includes etching the preliminary common inorganic layer for a set period of time or etching the preliminary common inorganic layer until a specific gas is detected.

Embodiments of the inventive concept provide a display panel including a base layer, a pixel definition layer disposed on the base layer, wherein a first light emitting opening and a second light emitting opening are defined in the pixel definition layer, a barrier wall disposed on the pixel definition layer, wherein a first barrier wall opening defined in the barrier wall overlaps the first light emitting opening and a second barrier wall opening defined in the barrier wall overlaps the second light emitting opening, a first light emitting element disposed in the first light emitting opening and the first barrier wall opening and including a first anode, a first light emitting pattern, and a first cathode that is in contact with the barrier wall, a second light emitting element disposed in the second light emitting opening and the second barrier wall opening and including a second anode, a second light emitting pattern, and a second cathode that is in contact with the barrier wall, a first lower encapsulation inorganic pattern covering the first light emitting element, a second lower encapsulation inorganic pattern spaced apart from the first lower encapsulation inorganic pattern and covering the second light emitting element, a first common inorganic layer covering a side surface of the first lower encapsulation inorganic pattern, a second common inorganic layer spaced apart from the first common inorganic layer and covering a side surface of the second lower encapsulation inorganic pattern, and an encapsulation organic layer covering an upper surface of the first lower encapsulation inorganic pattern, an upper surface of the second lower encapsulation inorganic pattern, the first common inorganic layer, and the second common inorganic layer.

Embodiments of the inventive concept provide an electronic device including a display module generating an image, a window disposed on the display module, and a housing disposed under the display module and coupled with the window. The display module includes a pixel definition layer, wherein a light emitting opening is defined in the pixel definition layer, a barrier wall disposed on the pixel definition layer, wherein a barrier wall opening defined in the barrier wall overlaps the light emitting opening, a light emitting element disposed in the light emitting opening and the barrier wall opening and including an anode, a light emitting pattern, and a cathode that is in contact with the barrier wall, a lower encapsulation inorganic pattern including a first portion disposed in the barrier wall opening and covering the light emitting element, a second portion extending from the first portion in a thickness direction of the pixel definition layer, and a third portion extending from the second portion and spaced apart from an upper surface of the barrier wall when viewed in a cross-section, and a common inorganic layer covering a side surface of the third portion of the lower encapsulation inorganic pattern.

The upper surface of the barrier wall, the second portion of the lower encapsulation inorganic pattern, the third portion of the lower encapsulation inorganic pattern, and the common inorganic layer define a separation area.

The display panel includes the common inorganic layer, and the common inorganic layer forms the separation area by covering the side surface of the lower encapsulation inorganic pattern. That is, a foreign substance is prevented from entering through a space between the lower encapsulation inorganic pattern and the barrier wall. As a result, pixel defects, such as, for example, a dark spot, a pixel shrinkage, or the like, on the display panel caused by the foreign substance are reduced or removed.

The common inorganic layer covers the side surface of the third portion of the lower encapsulation inorganic pattern (e.g., only the side surface of the third portion of the lower encapsulation inorganic pattern) without covering the upper surface of the lower encapsulation inorganic pattern. Accordingly, the display panel including the common inorganic layer covering the side surface of the lower encapsulation inorganic pattern, in which the common inorganic layer does not cover the upper surface of the lower encapsulation inorganic pattern, has improved optical characteristics, such as, for example, brightness, optical efficiency, or the like, compared to a display panel including a common inorganic layer covering an entire surface of a lower encapsulation inorganic pattern.

### BRIEF DESCRIPTION OF THE DRAWINGS

The above and other advantages of the present disclosure will become readily apparent by reference to the following detailed description when considered in conjunction with the accompanying drawings wherein:

FIG. 1A is a perspective view of an electronic device according to an embodiment of the present disclosure;

FIG. 1B is an exploded perspective view of an electronic device according to an embodiment of the present disclosure;

FIG. 2 is a cross-sectional view of a display module according to an embodiment of the present disclosure;

FIG. 3 is a plan view of a display panel according to an embodiment of the present disclosure;

FIG. 4 is an enlarged plan view of a portion of a display area of a display panel according to an embodiment of the present disclosure;

FIG. 5 is a cross-sectional view of a display panel taken along a line I-I′ of FIG. 3;

FIG. 6 is a cross-sectional view of a display panel taken along a line II-II′ of FIG. 4;

FIGS. 7A to 7N are cross-sectional views illustrating a method of manufacturing a display panel according to an embodiment of the present disclosure;

FIG. 8 is a cross-sectional view of a display panel taken along a line I-I′ of FIG. 3; and

FIG. 9 is a cross-sectional view of a display panel taken along a line I-I′ of FIG. 3.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, and the like may be used herein to describe various elements, these elements should not be limited by these terms. These terms are used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as illustrated in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within +30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

The term “adjacent” herein may refer to elements which are relatively close to each other (e.g., within a target distance). In some other cases, the term “adjacent’ herein may refer to elements which are in contact with each other.

It is to be understood that characteristics described herein with respect to relative terms such as, for example, “high,” “low,” and the like refer to the characteristics satisfying (e.g., being greater than, less than, or the like) a threshold associated with the characteristics.

Descriptions herein that an element (e.g., a layer, a pattern) “may be provided with” another element (e.g., an opening) include descriptions of the other element being formed in or on the element.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to accompanying drawings.

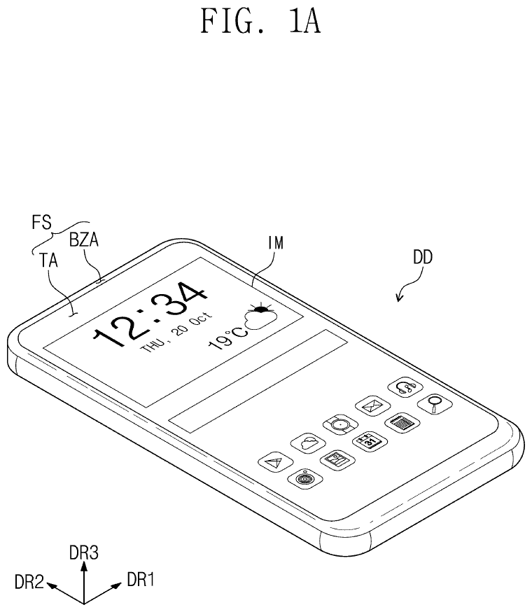

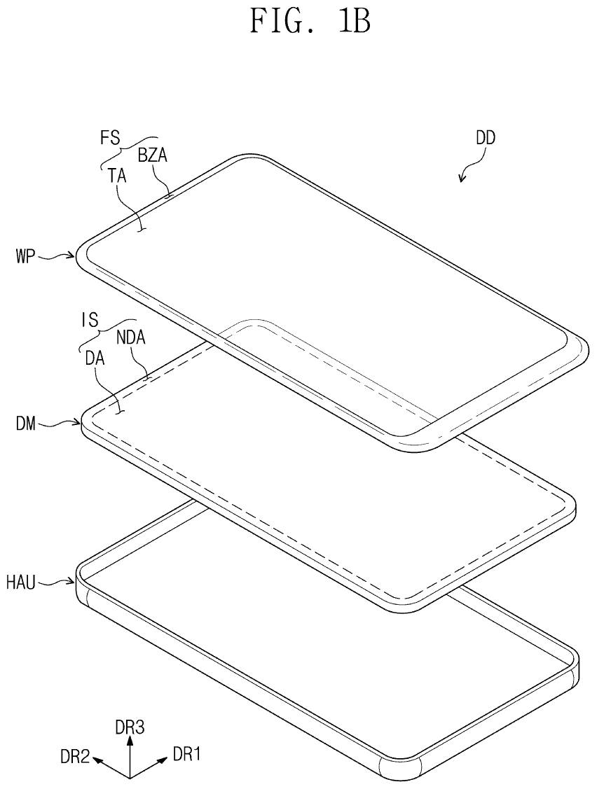

FIG. 1A is a perspective view of an electronic device DD according to an embodiment of the present disclosure, and FIG. 1B is an exploded perspective view of the electronic device DD according to an embodiment of the present disclosure.

The electronic device DD may be applied to a large-sized electronic item, such as, for example, a television set, a monitor, or an outdoor billboard. In some aspects, the electronic device DD may be applied to a small and medium-sized electronic item, such as, for example, a personal computer, a notebook computer, a personal digital assistant, a car navigation unit, a game unit, a smartphone, a tablet computer, and a camera. However, these are examples, and the electronic device DD may be employed in other display devices as long as the display devices do not deviate from the concept of the present disclosure. In FIGS. 1A and 1B, the smartphone will be described as a representative example of the electronic device DD.

Referring to FIGS. 1A and 1B, the electronic device DD may display an image IM through a display surface FS, which is substantially parallel to each of a first direction DR1 and a second direction DR2, toward a third direction DR3. The image IM may include a video and a still image. FIG. 1A illustrates a clock widget and application icons as a representative example of the image IM. The display surface FS through which the image IM is displayed may correspond to a front surface of the electronic device DD.

In the present embodiment, front (or upper) and rear (or lower) surfaces of each member of the electronic device DD may be defined with respect to a direction in which the image IM is displayed. The front and rear surfaces may be opposite to each other in the third direction DR3, and a normal line direction of each of the front and rear surfaces may be substantially parallel to the third direction DR3. The directions indicated by the first, second, and third directions DR1, DR2, and DR3 may be relative to each other, and thus, the directions indicated by the first, second, and third directions DR1, DR2, and DR3 may be changed to other directions. In the following descriptions, the expression “when viewed in a plane” means a state of being viewed in the third direction DR3.

The electronic device DD may include a window WP, a display module DM, and a housing HAU. The window WP and the housing HAU may be coupled to each other and provide an exterior of the electronic device DD.

The window WP may include an optically transparent insulating material. For example, the window WP may include a glass or plastic material. A front surface of the window WP may define the display surface FS of the electronic device DD. The display surface FS may include a transmissive area TA and a bezel area BZA. The transmissive area TA may be an optically transparent area. For example, the transmissive area TA may be an area having a visible light transmittance of about 90% or more.

The bezel area BZA may be an area having a relatively lower transmittance than the transmittance of the transmissive area TA. The bezel area BZA may define a shape of the transmissive area TA. The bezel area BZA may be disposed adjacent to the transmissive area TA and may surround the transmissive area TA. However, this is one example, and the bezel area BZA may be omitted from the window WP according to the embodiment of the present disclosure. The window WP may include at least one functional layer of an anti-fingerprint layer, a hard coating layer, and an anti-reflective layer and should not be particularly limited.

The display module DM may be disposed under the window WP. The display module DM may have a configuration that substantially generates the image IM. The image IM generated by the display module DM may be displayed through a display surface IS of the display module DM and may be viewed by a user through the transmissive area TA.

The display module DM may include a display area DA and a non-display area NDA. The display area DA may be activated in response to electrical signals. The non-display area NDA may be defined adjacent to the display area DA. The non-display area NDA may surround the display area DA. The non-display area NDA may be covered by the bezel area BZA and may not be viewed from the outside.

The housing HAU may be coupled with the window WP. The housing HAU and the window WP coupled with the housing HAU may provide an inner space. The display module DM may be accommodated in the inner space.

The housing HAU may include a material with a relatively high rigidity. For example, the housing HAU may include a glass, plastic, or metal material or a plurality of frames and/or plates of combinations thereof. The housing HAU may stably protect the components of the electronic device DD accommodated in the inner space from external impacts.

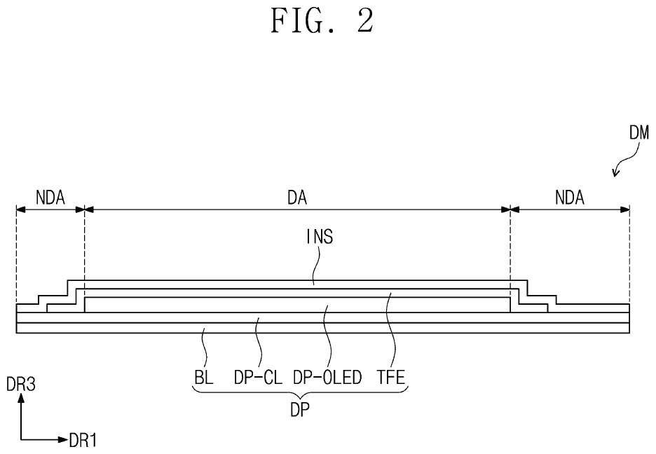

FIG. 2 is a cross-sectional view of the display module DM according to an embodiment of the present disclosure.

Referring to FIG. 2, the display module DM may include a display panel DP and an input sensor INS. Although not illustrated in figures, the electronic device DD (refer to FIG. 1A) may further include a protective member disposed on a lower surface of the display panel DP or an anti-reflective member and/or a window member disposed on an upper surface of the input sensor INS.

The display panel DP may be a light emitting type display panel, however, the display panel DP should not be particularly limited. For example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot, a quantum rod, or a micro-LED. Hereinafter, the organic light emitting display panel will be described as the display panel DP.

The display panel DP may include a base layer BL, a circuit element layer DP-CL, a display element layer DP-OLED, and a thin film encapsulation layer TFE. The circuit element layer DP-CL, the display element layer DP-OLED, and the thin film encapsulation layer TFE may be disposed on the base layer BL. The input sensor INS may be disposed directly on the thin film encapsulation layer TFE. In the present disclosure, the expression “A component A is disposed directly on a component B.” means that no adhesive layers are present between the component A and the component B.

The base layer BL may include at least one plastic film. The base layer BL may be a flexible substrate and may include a plastic substrate, a glass substrate, a metal substrate, or an organic/inorganic composite material substrate. In the present disclosure, the display area DA and the non-display area NDA described with reference to FIG. 1B may be defined in the base layer BL of FIG. 2.

The circuit element layer DP-CL may include at least one insulating layer and a circuit element. The insulating layer may include at least one inorganic layer and at least one organic layer. The circuit element may include signal lines and a pixel driving circuit.

The display element layer DP-OLED may include a barrier wall and a light emitting element. The light emitting element may include an anode, a light emitting pattern, and a cathode.

The thin film encapsulation layer TFE may include a plurality of thin layers. Some thin layers may be disposed to improve an optical efficiency, and some thin layers may be disposed to protect organic light emitting diodes.

The input sensor INS may obtain coordinate information of an external input. The input sensor INS may have a multi-layer structure. The input sensor INS may include a conductive layer having a single-layer or multi-layer structure. The input sensor INS may include an insulating layer having a single-layer or multi-layer structure. The input sensor INS may sense the external input by a capacitive method. However, the operation method of the input sensor INS should not be particularly limited. The input sensor INS may sense the external input by an electromagnetic induction method or a pressure sensing method. According to an embodiment, the input sensor INS may be omitted.

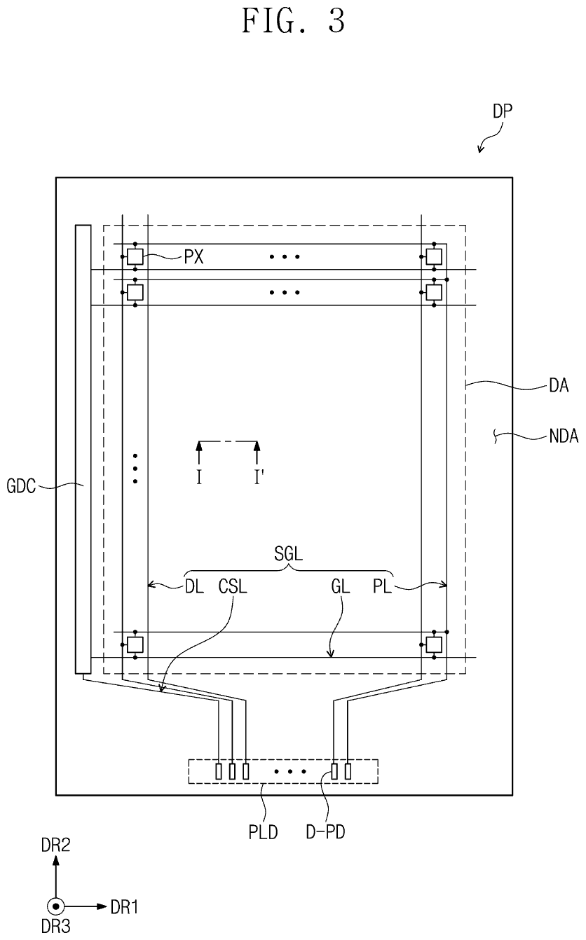

FIG. 3 is a plan view of the display panel DP according to an embodiment of the present disclosure.

Referring to FIG. 3, the display panel DP may include the display area DA and the non-display area NDA around the display area DA. The display panel DP may include pixels PX disposed in the display area DA and signal lines SGL electrically connected to the pixels PX. The display panel DP may include a driving circuit GDC and a pad part PLD. The display area DA and the non-display area NDA may be distinguished from each other by a presence or absence of the pixels PX. The pixels PX may be disposed in the display area DA. The driving circuit GDC and the pad part PLD may be disposed in the non-display area NDA.

The pixels PX may be arranged in the first direction DR1 and the second direction DR2. The pixels PX may include a plurality of pixel rows extending in the first direction DR1 and arranged in the second direction DR2 and a plurality of pixel columns extending in the second direction DR2 and arranged in the first direction DR1.

The signal lines SGL may include gate lines GL, data lines DL, a power line PL, and a control signal line CSL. Each of the gate lines GL may be connected to a corresponding pixel among the pixels PX, and each of the data lines DL may be connected to a corresponding pixel among the pixels PX. The power line PL may be electrically connected to the pixels PX. The control signal line CSL may be connected to the driving circuit GDC and may provide control signals to the driving circuit GDC.

The driving circuit GDC may include a gate driving circuit. The gate driving circuit may generate gate signals and may sequentially output the generated gate signals to the gate lines GL. The gate driving circuit may further output another control signal to the pixel driving circuit.

The pad part PLD may be connected to a flexible circuit board (not illustrated). The pad part PLD may include pixel pads D-PD, and the pixel pads D-PD may be pads that connect the flexible circuit board to the display panel DP. Each of the pixel pads D-PD may be connected to a corresponding signal line among the signal lines SGL. The pixel pads D-PD may be connected to corresponding pixels PX via the signal lines SGL. In some aspects, one pixel pad among the pixel pads D-PD may be connected to the driving circuit GDC.

In some aspects, the pad part PLD may further include input pads. The input pads may be pads that connect the flexible circuit board (not illustrated) to the input sensor INS (refer to FIG. 2), however, the present disclosure should not be limited thereto or thereby. According to an embodiment, the input pads may be disposed in the input sensor INS (refer to FIG. 2) and may be connected to a separate circuit board different from the flexible circuit board to which the pixel pads D-PD are connected. According to an embodiment, the input sensor INS (refer to FIG. 2) may be omitted and may not further include the input pads.

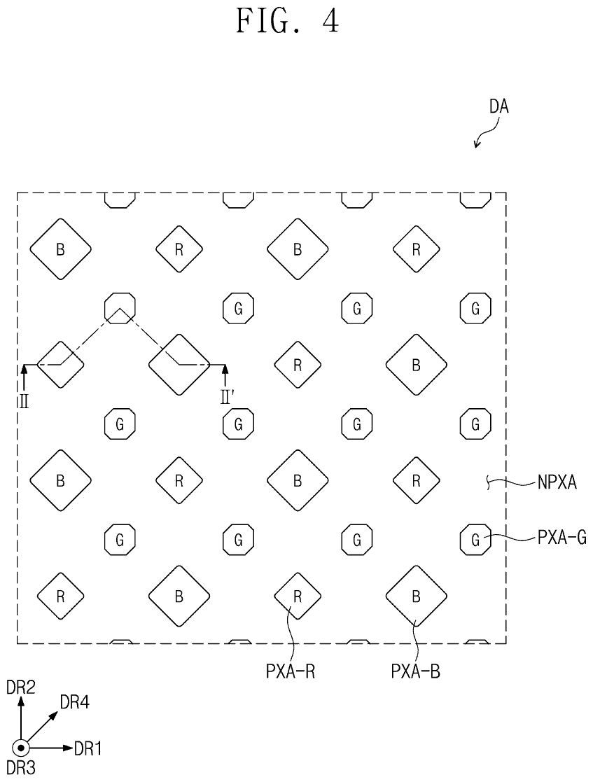

FIG. 4 is an enlarged plan view of a portion of the display area DA of the display panel DP (refer to FIG. 2) according to an embodiment of the present disclosure. FIG. 4 is a plan view illustrating the display module DM (refer to FIG. 1B) when viewed from the above of the display surface IS (refer to FIG. 1B) of the display module DM (refer to FIG. 1B) and illustrates an arrangement of light emitting areas PXA-R, PXA-G, and PXA-B.

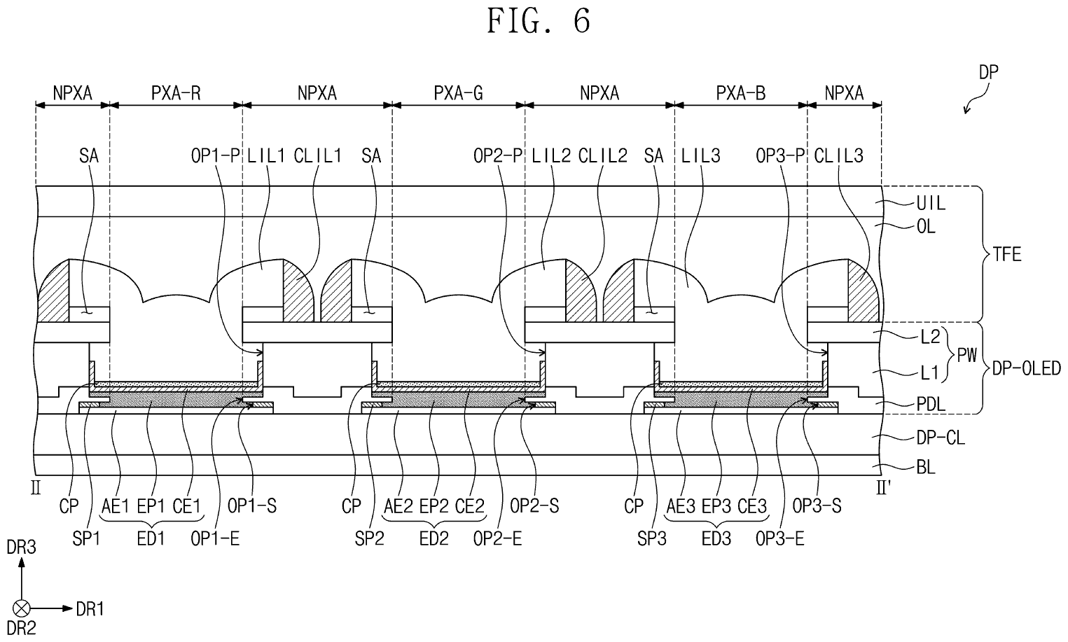

Referring to FIG. 4, the display area DA may include first, second, and third light emitting areas PXA-R, PXA-G, and PXA-B and a peripheral area NPXA surrounding the first, second, and third light emitting areas PXA-R, PXA-G, and PXA-B. The first, second, and third light emitting areas PXA-R, PXA-G, and PXA-B may respectively correspond to areas from which lights provided from light emitting elements ED1, ED2, and ED3 (refer to FIG. 6) are emitted. The first, second, and third light emitting areas PXA-R, PXA-G, and PXA-B may be distinguished by colors of the lights emitted outward from the display module DM (refer to FIG. 2).

The first, second, and third light emitting areas PXA-R, PXA-G, and PXA-B may respectively provide first, second, and third color lights having colors different from each other. As an example, the first color light may be a red light, the second color light may be a green light, and the third color light may be a blue light. However, the first, second, and third color lights should not be limited thereto or thereby.

Each of the first, second, and third light emitting areas PXA-R, PXA-G, and PXA-B may be defined as an area through which an upper surface of the anode is exposed by a light emitting opening described later. The peripheral area NPXA may define a boundary between the first, second, and third light emitting areas PXA-R, PXA-G, and PXA-B and may prevent a mixture of the colors of the lights between the first, second, and third light emitting areas PXA-R, PXA-G, and PXA-B.

Each of the first, second, and third light emitting areas PXA-R, PXA-G, and PXA-B may be provided in plural and may be repeatedly arranged in an arrangement within the display area DA. As an example, the first and third light emitting areas PXA-R and PXA-B may be alternately arranged with each other in the first direction DR1 to form a first group. The second light emitting areas PXA-G may be arranged in the first direction DR1 to form a second group. Each of the first group and the second group may be provided in plural, and the first groups may be alternately arranged with the second groups in the second direction DR2.

One second light emitting area PXA-G may be disposed spaced apart from one first light emitting area PXA-R or one third light emitting area PXA-B in a fourth direction DR4. The fourth direction DR4 may correspond to a direction between the first and second directions DR1 and DR2.

FIG. 4 illustrates a representative example of the arrangement of the first, second, and third light emitting areas PXA-R, PXA-G, and PXA-B, and the arrangement of the first, second, and third light emitting areas PXA-R, PXA-G, and PXA-B should not be particularly limited and may be changed in various ways. The first, second, and third light emitting areas PXA-R, PXA-G, and PXA-B may be arranged in a pentile pattern (PENTILE™) as illustrated in FIG. 4. According to an embodiment, the first, second, and third light emitting areas PXA-R, PXA-G, and PXA-B may be arranged in a stripe pattern or a diamond pattern (Diamond Pixel™).

Each of the first, second, and third light emitting areas PXA-R, PXA-G, and PXA-B may have a variety of shapes when viewed in a plane. As an example, each of the first, second, and third light emitting areas PXA-R, PXA-G, and PXA-B may have a polygonal shape, a circular shape, or an oval shape. In FIG. 4, the first and third light emitting areas PXA-R and PXA-B each having a quadrangular shape (or a lozenge shape) and the second light emitting area PXA-G having an octagonal shape are illustrated as a representative example.

The first, second, and third light emitting areas PXA-R, PXA-G, and PXA-B may have substantially the same shape as each other when viewed in the plane, or at least one of the first, second, and third light emitting areas PXA-R, PXA-G, and PXA-B may have a shape different from the others. FIG. 4 illustrates a structure in which the first and third light emitting areas PXA-R and PXA-B have the same shape as each other when viewed in the plane and the second light emitting area PXA-G has a shape different from the shapes of the first and third light emitting areas PXA-R and PXA-B as a representative example.

At least one of the first, second, and third light emitting areas PXA-R, PXA-G, and PXA-B may have a size different from those of the others when viewed in the plane. The size of the first light emitting area PXA-R emitting the red light may be greater than the size of the second light emitting area PXA-G emitting the green light and may be smaller than the size of the third light emitting area PXA-B emitting the blue light. However, a size relationship between the first, second, and third light emitting areas PXA-R, PXA-G, and PXA-B according to the colors of the emitted lights should not be limited thereto or thereby and may be changed in various ways depending on a design of the display module DM (refer to FIG. 2). In some aspects, according to an embodiment, the first, second, and third light emitting areas PXA-R, PXA-G, and PXA-B may have substantially the same size as each other when viewed in the plane.

The shape, size, and arrangement of the first, second, and third light emitting areas PXA-R, PXA-G, and PXA-B of the display module DM (refer to FIG. 2) may be variously designed depending on the colors of the emitted lights, the size of the display module DM (refer to FIG. 2), and the configuration of the display module DM (refer to FIG. 2), and the shape, size, and arrangement of the first, second, and third light emitting areas PXA-R, PXA-G, and PXA-B should not be limited to the embodiment illustrated in FIG. 4.

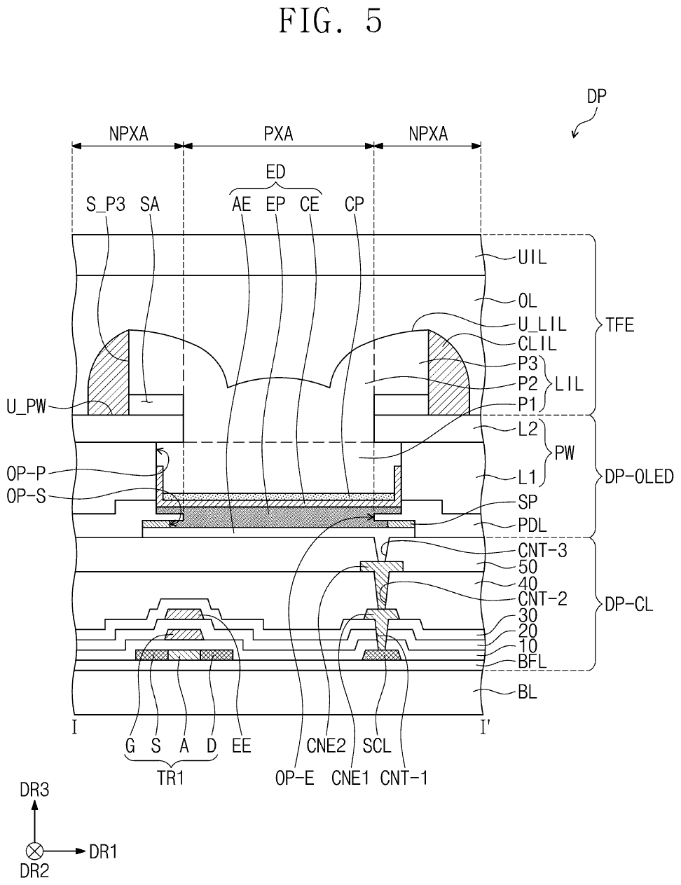

FIG. 5 is a cross-sectional view of the display panel DP taken along a line I-I′ of FIG. 3. In FIG. 5, the same reference numerals denote the same elements in FIG. 2, and thus, detailed descriptions of the same elements will be omitted. FIG. 5 is an enlarged view of one light emitting area PXA of the display area DA (refer to FIG. 4), and the light emitting area PXA of FIG. 5 corresponds to one of the first, second, and third light emitting areas PXA-R, PXA-G, and PXA-B of FIG. 4.

Referring to FIG. 5, the display panel DP may include the base layer BL, the circuit element layer DP-CL, the display element layer DP-OLED, and the thin film encapsulation layer TFE.

The display panel DP may include a plurality of insulating layers, a semiconductor pattern, a conductive pattern, and a signal line. An insulating layer, a semiconductor layer, and a conductive layer may be formed by a coating or depositing process. Then, the insulating layer, the semiconductor layer, and the conductive layer may be selectively patterned by a photolithography process and an etching process. The semiconductor pattern, the conductive pattern, and the signal line included in the circuit element layer DP-CL and the display element layer DP-OLED may be formed through the processes described herein.

The circuit element layer DP-CL may be disposed on the base layer BL. The circuit element layer DP-CL may include a buffer layer BFL, a transistor TR1, a signal transmission area SCL, first, second, third, fourth, and fifth insulating layers 10, 20, 30, 40, and 50, an electrode EE, and a plurality of connection electrodes CNE1 and CNE2.

The buffer layer BFL may be disposed on the base layer BL. The buffer layer BFL may increase an adhesion between the base layer BL and the semiconductor pattern. The buffer layer BFL may include a silicon oxide layer and a silicon nitride layer, and the silicon oxide layer and the silicon nitride layer may be alternately stacked with each other.

The semiconductor pattern may be disposed on the buffer layer BFL. The semiconductor pattern may include polysilicon, however, the semiconductor pattern should not be limited thereto or thereby. The semiconductor pattern may include an amorphous silicon or metal oxide. FIG. 5 illustrates a portion of the semiconductor pattern, and the semiconductor pattern may be further disposed in the light emitting areas PXA-R, PXA-G, and PXA-B (refer to FIG. 4). The semiconductor pattern may be arranged with a specific rule over the light emitting areas PXA-R, PXA-G, and PXA-B (refer to FIG. 4). The semiconductor pattern may have different electrical properties depending on whether the semiconductor pattern is doped or not. The semiconductor pattern may include a first region having a relatively high doping concentration and a second region having a relatively low doping concentration. The first region may be doped with an N-type dopant or a P-type dopant. A P-type transistor may include the first region doped with the P-type dopant.

The first region may have a conductivity greater than a conductivity of the second region and may substantially serve as an electrode or a signal line. The second region may substantially correspond to an active (or a channel) of the transistor. In other words, a portion of the semiconductor pattern may be the active of the transistor, another portion of the semiconductor pattern may be a source or a drain of the transistor, and the other portion of the semiconductor pattern may be a conductive area.

A source S, an active A, and a drain D of the transistor TR1 may be formed from the semiconductor pattern. FIG. 5 illustrates a portion of the signal transmission area SCL formed from the semiconductor pattern. Although not illustrated in figures, the signal transmission area SCL may be connected to the drain D of the transistor TR1 in a plane.

The first, second, third, fourth, and fifth insulating layers 10, 20, 30, 40, and 50 may be disposed on the buffer layer BFL. Each of the first to fifth insulating layers 10 to 50 may be an inorganic layer or an organic layer.

The first insulating layer 10 may be disposed on the buffer layer BFL. The first insulating layer 10 may cover the source S, the active A, and the drain D of the transistor TR1 and the signal transmission area SCL disposed on the buffer layer BFL. A gate G of the transistor TR1 may be disposed on the first insulating layer 10. The second insulating layer 20 may be disposed on the first insulating layer 10 and may cover the gate G. The electrode EE may be disposed on the second insulating layer 20. The third insulating layer 30 may be disposed on the second insulating layer 20 and may cover the electrode EE.

A first connection electrode CNE1 may be disposed on the third insulating layer 30. The first connection electrode CNE1 may be connected to the signal transmission area SCL via a contact hole CNT-1 defined through the first, second, and third insulating layers 10, 20, and 30. The fourth insulating layer 40 may be disposed on the third insulating layer 30 and may cover the first connection electrode CNE1. The fourth insulating layer 40 may be an organic layer.

A second connection electrode CNE2 may be disposed on the fourth insulating layer 40. The second connection electrode CNE2 may be connected to the first connection electrode CNE1 via a contact hole CNT-2 defined through the fourth insulating layer 40. The fifth insulating layer 50 may be disposed on the fourth insulating layer 40 and may cover the second connection electrode CNE2. The fifth insulating layer 50 may be an organic layer.

The display element layer DP-OLED may be disposed on the circuit element layer DP-CL. The display element layer DP-OLED may include the light emitting element ED, a sacrificial pattern SP, a pixel definition layer PDL, and the barrier wall PW.

The light emitting element ED may include an anode AE (or a first electrode), the light emitting pattern EP, and a cathode CE (or a second electrode). The light emitting element ED may be disposed in a light emitting opening OP-E and a barrier wall opening OP-P.

The anode AE may be disposed on the fifth insulating layer 50 of the circuit element layer DP-CL. The anode AE may be a transmissive electrode, a semi-transmissive electrode, or a reflective electrode. The anode AE may be connected to the second connection electrode CNE2 via a connection contact hole CNT-3 defined through the fifth insulating layer 50. Accordingly, the anode AE may be electrically connected to the signal transmission area SCL via the first and second connection electrodes CNE1 and CNE2 and may be electrically connected to a corresponding circuit element. The anode AE may have a single-layer or multi-layer structure. The anode AE may include plural layers containing ITO or Ag. As an example, the anode AE may include a layer (or a lower ITO layer) containing ITO, a layer (or an Ag layer) disposed on the lower ITO layer and containing Ag, and a layer (or an upper ITO layer) disposed on the Ag layer and containing ITO.

The sacrificial pattern SP may be disposed between the anode AE and the pixel definition layer PDL. A sacrificial opening OP-S may be defined in the sacrificial pattern SP and expose a portion of the upper surface of the anode AE. The sacrificial opening OP-S may overlap the light emitting opening OP-E described later.

The pixel definition layer PDL may be disposed on the fifth insulating layer 50 of the circuit element layer DP-CL. The light emitting opening OP-E may be defined in the pixel definition layer PDL. The light emitting opening OP-E may correspond to the anode AE, and at least a portion of the anode AE may be exposed through the light emitting opening OP-E of the pixel definition layer PDL.

In some aspects, the light emitting opening OP-E may correspond to the sacrificial opening OP-S of the sacrificial pattern SP. According to the present embodiment, the upper surface of the anode AE may be spaced apart from the pixel definition layer PDL, with the sacrificial pattern SP interposed between the upper surface of the anode AE and the pixel definition layer PDL, when viewed in a cross-section, and thus, damage to the anode AE may be prevented in a process of forming the light emitting opening OP-E.

When viewed in the plane, a size of the light emitting opening OP-E may be smaller than a size of the sacrificial opening OP-S. That is, an inner side surface of the pixel definition layer PDL, which defines the light emitting opening OP-E, may be closer to a center of the anode AE than an inner side surface of the sacrificial pattern SP, which defines the sacrificial opening OP-S, is. However, the present disclosure should not be limited thereto or thereby. According to an embodiment, the inner side surface of the sacrificial pattern SP, which defines the sacrificial opening OP-S, may be substantially aligned with the inner side surface of the pixel definition layer PDL, which defines the corresponding light emitting opening OP-E. In this case, the light emitting area PXA may be an area of the anode AE exposed through the corresponding sacrificial opening OP-S.

The pixel definition layer PDL may include an inorganic insulating material. As an example, the pixel definition layer PDL may include silicon nitride (SiNₓ). The pixel definition layer PDL may be disposed between the anode AE and the barrier wall PW and may prevent the anode AE from being electrically connected to the barrier wall PW.

The light emitting pattern EP may be disposed on the anode AE. The light emitting pattern EP may include a light emitting layer including a light emitting material. The light emitting pattern EP may further include a hole injection layer and a hole transport layer, which are disposed between the anode AE and the light emitting layer, and may further include an electron transport layer and an electron injection layer, which are disposed on the light emitting layer. The light emitting pattern EP may be referred to as an organic layer or an intermediate layer.

The light emitting pattern EP may be patterned by a tip portion defined in the barrier wall PW. The process of patterning the light emitting pattern EP will be described in a method of manufacturing the display panel. The light emitting pattern EP may be disposed inside the sacrificial opening OP-S and the light emitting opening OP-E, however, this is an example. The light emitting pattern EP may be disposed inside at least one of the sacrificial opening OP-S, the light emitting opening OP-E, and the barrier wall opening OP-P. The light emitting pattern EP may cover a portion of the upper surface of the pixel definition layer PDL.

The cathode CE may be disposed on the light emitting pattern EP. The cathode CE may be patterned by the tip portion defined in the barrier wall PW. At least a portion of the cathode CE may be disposed in the barrier wall opening OP-P. FIG. 5 illustrates a structure in which the cathode CE is disposed in the light emitting opening OP-E and the barrier wall opening OP-P, however, the present disclosure should not be limited thereto or thereby. As an example, the cathode CE may be disposed in the barrier wall opening OP-P, without being disposed in the light emitting opening OP-E.

The cathode CE may extend along a first inner side surface of a first barrier wall layer L1, and an end of the cathode CE may be in contact with the first barrier wall layer L1. FIG. 5 illustrates a structure in which the cathode CE is in contact with the first inner side surface of the first barrier wall layer L1 and the inner side surface of the pixel definition layer PDL, however, the present disclosure should not be limited thereto or thereby. As an example, the cathode CE may be in contact with the first inner side surface of the first barrier wall layer L1, without being in contact with the inner side surface of the pixel definition layer PDL.

The cathode CE may have a conductivity. The cathode CE may be formed from a variety of materials having conductivity, such as, for example, metals, transparent conductive oxides (TCOs), conductive polymer materials, or other materials having conductivity. As an example, the cathode CE may include silver (Ag), magnesium (Mg), lead (Pb), copper (Cu), or compounds thereof.

The display element layer DP-OLED may further include a capping pattern CP. The capping pattern CP may be disposed in the barrier wall opening OP-P and may be disposed on the cathode CE. The capping pattern CP may be patterned by the tip portion defined in the barrier wall PW. According to an embodiment, the capping pattern CP may be omitted.

The barrier wall PW may be disposed on the pixel definition layer PDL. The barrier wall opening OP-P may be defined in the barrier wall PW. The barrier wall opening OP-P may correspond to the light emitting opening OP-E, and at least a portion of the anode AE may be exposed through the barrier wall opening OP-P.

The barrier wall PW may include a plurality of layers sequentially stacked. As an example, the barrier wall PW may include the first barrier wall layer L1 and a second barrier wall layer L2. The first barrier wall layer L1 may be disposed on the pixel definition layer PDL, and the second barrier wall layer L2 may be disposed on the first barrier wall layer L1. As illustrated in FIG. 5, the first barrier wall layer L1 may have a thickness greater than a thickness of the second barrier wall layer L2, however, the first barrier wall layer L1 and the second barrier wall layer L2 should not be limited thereto or thereby.

Each of the first barrier wall layer L1 and the second barrier wall layer L2 may include a conductive material. As an example, the conductive material may include metal, transparent conductive oxide (TCO), or a combination thereof. As an example, the metal may include gold (Au), silver (Ag), aluminum (Al), magnesium (Mg), lithium (Li), molybdenum (Mo), titanium (Ti), copper (Cu), or an alloy. The transparent conductive oxide (TCO) may include indium tin oxide (ITO), indium zinc oxide (IZO), zinc oxide, indium oxide, indium gallium oxide, indium gallium zinc oxide (IGZO), or aluminum zinc oxide.

The barrier wall PW may have an undercut shape in the cross-section. At least one of the layers of the barrier wall PW may be recessed relative to other layers. Accordingly, the barrier wall PW may include the tip portion. As an example, the first barrier wall layer L1 may be undercut with respect to the second barrier wall layer L2. The second barrier wall layer L2 may protrude more toward the light emitting opening OP-E than the first barrier wall layer L1 to form the tip portion. The portion of the second barrier wall layer L2 that protrudes further from the first barrier wall layer L1 toward the light emitting area PXA may be defined as the tip portion in the barrier wall PW. That is, a second inner side surface of the second barrier wall layer L2 may be closer to the center of the anode AE than the first inner side surface of the first barrier wall layer L1 is.

FIG. 5 illustrates a structure in which each of the first inner side surface of the first barrier wall layer L1 and the second inner side surface of the second barrier wall layer L2 extends vertically with respect to the upper surface of the pixel definition layer PDL as a representative example, however, the present disclosure should not be limited thereto or thereby. As an example, the barrier wall PW may have a tapered shape or a reverse tapered shape.

The barrier wall PW may receive a driving voltage. Accordingly, the cathode CE may be electrically connected to the barrier wall PW, and thus, the cathode CE may receive the driving voltage.

The thin film encapsulation layer TFE may be disposed on the display element layer DP-OLED. The thin film encapsulation layer TFE may include a lower encapsulation inorganic pattern LIL, a common inorganic layer CLIL, an encapsulation organic layer OL, and an upper encapsulation inorganic layer UIL.

The lower encapsulation inorganic pattern LIL may be disposed such that the lower encapsulation inorganic pattern LIL overlaps the light emitting opening OP-E. The lower encapsulation inorganic pattern LIL may be disposed on the capping pattern CP and cover the light emitting element ED. A portion of the lower encapsulation inorganic pattern LIL may be disposed inside the barrier wall opening OP-P, and the other portion of the lower encapsulation inorganic pattern LIL may be disposed on the barrier wall PW.

The lower encapsulation inorganic pattern LIL may include a first portion P1, a second portion P2, and a third portion P3. The first portion P1 may be disposed in the barrier wall opening OP-P and cover the light emitting element ED, and the second portion P2 may extend from the first portion P1 in a thickness direction of the base layer BL, e.g., the third direction DR3. The third portion P3 may extend from the second portion P2 and may be spaced apart from an upper surface U_PW of the barrier wall PW when viewed in the cross-section.

The common inorganic layer CLIL may cover the lower encapsulation inorganic pattern LIL. The common inorganic layer CLIL may cover a side surface S_P3 of the third portion P3 of the lower encapsulation inorganic pattern LIL. In other words, an upper surface U_LIL of the lower encapsulation inorganic pattern LIL may not be covered by the common inorganic layer CLIL. The common inorganic layer CLIL may include an inorganic material. As an example, the common inorganic layer CLIL may include at least one of silicon oxide (SiOₓ), silicon nitride (SiNₓ), and silicon oxynitride (SiON).

A separation area SA may be defined by the upper surface U_PW of the barrier wall PW, the second portion P2 and the third portion P3 of the lower encapsulation inorganic pattern LIL, and the common inorganic layer CLIL. As the third portion P3 of the lower encapsulation inorganic pattern LIL is spaced apart from the upper surface U_PW of the barrier wall PW when viewed in the cross-section and the common inorganic layer CLIL covers the side surface S_P3 of the lower encapsulation inorganic pattern LIL, the separation area SA may be formed. The separation area SA may be an empty area. As an example, the separation area SA may be filled with gas. The separation area SA may be defined as surrounding the second portion P2 of the lower encapsulation inorganic pattern LIL when viewed in the plane.

The encapsulation organic layer OL may be disposed on the lower encapsulation inorganic pattern LIL and the common inorganic layer CLIL. The encapsulation organic layer OL may cover the lower encapsulation inorganic pattern LIL and the common inorganic layer CLIL and may provide a flat upper surface thereon. Since the common inorganic layer CLIL does not cover the upper surface U_LIL of the lower encapsulation inorganic pattern LIL, the encapsulation organic layer OL may be directly in contact with the upper surface U_LIL of the lower encapsulation inorganic pattern LIL. The separation area SA may be spaced apart from the encapsulation organic layer OL. The upper encapsulation inorganic layer UIL may be disposed on the encapsulation organic layer OL.

The lower encapsulation inorganic pattern LIL, the common inorganic layer CLIL, and the upper encapsulation inorganic layer UIL may protect the display element layer DP-OLED from moisture and oxygen, and the encapsulation organic layer OL may protect the display element layer DP-OLED from a foreign substance such as, for example, dust particles.

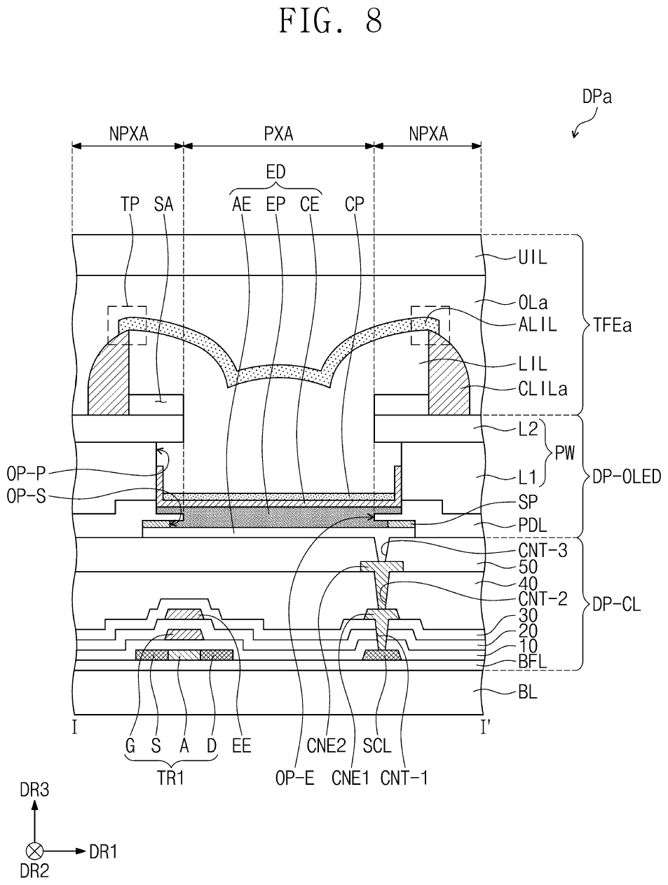

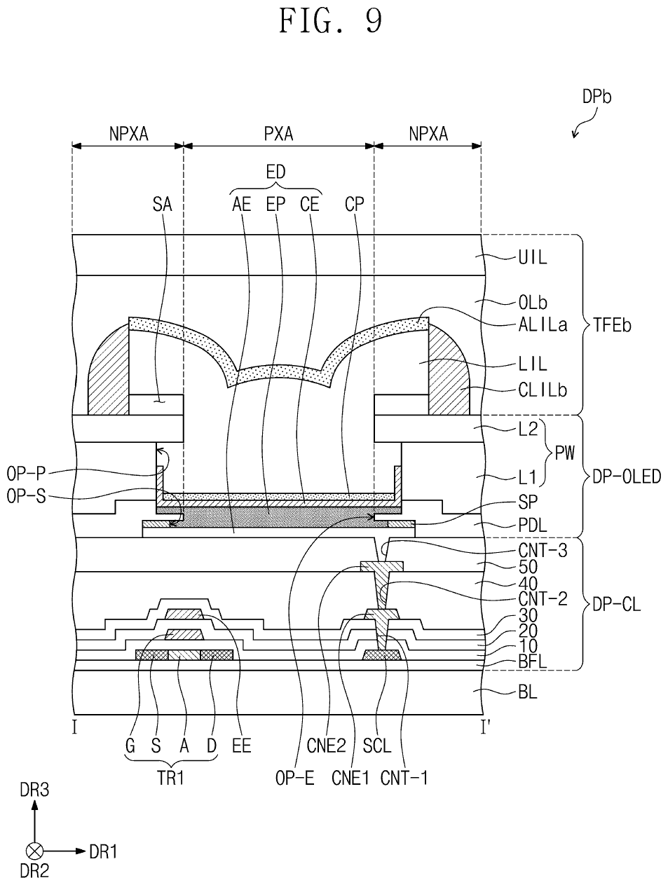

FIG. 5 illustrates the structure in which the thin film encapsulation layer TFE includes the lower encapsulation inorganic pattern LIL, the common inorganic layer CLIL, the encapsulation organic layer OL, and the upper encapsulation inorganic layer UIL as a representative example, however, the present disclosure should not be limited thereto or thereby. As an example, the thin film encapsulation layer TFE may further include an additional encapsulation inorganic pattern (refer to ALIL of FIG. 8 or ALILa of FIG. 9) disposed between the lower encapsulation inorganic pattern LIL and the common inorganic layer CLIL.

According to the present disclosure, the display panel DP may include the common inorganic layer CLIL, and the common inorganic layer CLIL may form the separation area SA by covering the side surface of the lower encapsulation inorganic pattern LIL. That is, a foreign substance may be prevented from entering through a space between the lower encapsulation inorganic pattern LIL and the barrier wall PW. As a result, pixel defects, such as, for example, a dark spot, a pixel shrinkage, or the like, on the display panel caused by the foreign substance may be reduced or removed.

In some aspects, the common inorganic layer CLIL may cover only the side surface S_P3 of the third portion P3 of the lower encapsulation inorganic pattern LIL without covering the upper surface U_LIL of the lower encapsulation inorganic pattern LIL. Accordingly, the display panel DP including the common inorganic layer CLIL covering only the side surface S_P3 of the lower encapsulation inorganic pattern LIL according to the present disclosure may have improved optical characteristics such as, for example, brightness, optical efficiency, or the like, compared to a display panel including a common inorganic layer covering an entire surface of a lower encapsulation inorganic pattern.

FIG. 6 is a cross-sectional view of the display panel taken along a line II-II′ of FIG. 4. FIG. 6 is an enlarged cross-sectional view of one first light emitting area PXA-R, one second light emitting area PXA-G, and one third light emitting area PXA-B, and the described herein regarding the light emitting area PXA of FIG. 5 may be equally applied to the first, second, and third light emitting areas PXA-R, PXA-G, and PXA-B.

Referring to FIG. 6, the display panel DP may include the base layer BL, the circuit element layer DP-CL, the display element layer DP-OLED, and the thin film encapsulation layer TFE. The display element layer DP-OLED may include the light emitting elements ED1, ED2, and ED3, sacrificial patterns SP1, SP2, and SP3, the pixel definition layer PDL, and the barrier wall PW.

The light emitting elements ED1, ED2, and ED3 may respectively include the first light emitting element ED1, the second light emitting element ED2, and the third light emitting element ED3, which emit different colors from each other. Each of the first light emitting element ED1, the second light emitting element ED2, and the third light emitting element ED3 may be provided in plural. For the sake of clarity, the first light emitting element ED1, the second light emitting element ED2, and the third light emitting element ED3 are described in singular form below.

The first light emitting element ED1 may include a first anode AE1, a first light emitting pattern EP1, and a first cathode CE1. The second light emitting element ED2 may include a second anode AE2, a second light emitting pattern EP2, and a second cathode CE2. The third light emitting element ED3 may include a third anode AE3, a third light emitting pattern EP3, and a third cathode CE3. The first, second, and third anodes AE1, AE2, and AE3 may be provided in plural patterns. The first light emitting pattern EP1 may provide the red light, the second light emitting pattern EP2 may provide the green light, and the third light emitting pattern EP3 may provide the blue light.

First, second, and third light emitting openings OP1-E, OP2-E, and OP3-E may be defined through the pixel definition layer PDL. At least a portion of the first anode AE1 may be exposed through the first light emitting opening OP1-E. At least a portion of the second anode AE2 may be exposed through the second light emitting opening OP2-E. At least a portion of the third anode AE3 may be exposed through the third light emitting opening OP3-E.

In the present embodiment, the first light emitting area PXA-R may be defined as an area of an upper surface of the first anode AE1, which is exposed through the first light emitting opening OP1-E. The second light emitting area PXA-G may be defined as an area of an upper surface of the second anode AE2, which is exposed through the second light emitting opening OP2-E. The third light emitting area PXA-B may be defined as an area of an upper surface of the third anode AE3, which is exposed through the third light emitting opening OP3-E.

The sacrificial patterns SP1, SP2, and SP3 may include a first sacrificial pattern SP1, a second sacrificial pattern SP2, and a third sacrificial pattern SP3. The first, second, and third sacrificial patterns SP1, SP2, and SP3 may be disposed on the upper surfaces of the first, second, and third anodes AE1, AE2, and AE3, respectively. First, second, and third sacrificial openings OP1-S, OP2-S, and OP3-S may be defined through the first, second, and third sacrificial patterns SP1, SP2, and SP3 to respectively correspond to the first, second, and third light emitting openings OP1-E, OP2-E, and OP3-E.

In the present embodiment, first, second, and third barrier wall openings OP1-P, OP2-P, and OP3-P may be defined through the barrier wall PW to respectively correspond to the first, second, and third light emitting openings OP1-E, OP2-E, and OP3-E.

In the present embodiment, the first, second, and third light emitting patterns EP1, EP2, and EP3 and the first, second, and third cathodes CE1, CE2, and CE3 may be physically separated from each other by the second barrier wall layer L2 forming the tip portion and may be respectively formed in the light emitting openings OP1-E, OP2-E, and OP3-E and the barrier wall openings OP1-P, OP2-P, and OP3-P. That is, the light emitting elements ED1, ED2, and ED3 may be disposed in the barrier wall openings OP1-P, OP2-P, and OP3-P and the light emitting openings OP1-E, OP2-E, and OP3-E. As an example, the first light emitting element ED1 may be disposed in the first barrier wall opening OP1-P and the first light emitting opening OP1-E, the second light emitting element ED2 may be disposed in the second barrier wall opening OP2-P and the second light emitting opening OP2-E, and the third light emitting element ED3 may be disposed in the third barrier wall opening OP3-P and the third light emitting opening OP3-E.

According to the present disclosure, the first light emitting patterns EP1 may be deposited after being patterned in the unit of pixel by the tip portion defined in the barrier wall PW. That is, the first light emitting patterns EP1 may be commonly formed using an open mask but may be easily divided into plural portions in the unit of pixel by the barrier wall PW.

In contrast, for example, in a case where the first light emitting patterns EP1 are patterned using a fine metal mask (FMM), a support spacer protruding from the conductive barrier wall may be required to support the fine metal mask. Since the fine metal mask is spaced apart from a base surface on which a patterning process is performed by a height of the barrier wall and the support spacer, there may be limitations to implementing a high resolution of the display device. As the fine metal mask is in contact with the support spacer, foreign substances may remain on the support spacer, or the support spacer may be damaged by getting scratches due to the fine metal mask after the patterning process of the first light emitting patterns EP1. Accordingly, defects may occur in the display panel.

According to the present embodiment, as the display panel DP includes the barrier wall PW, the light emitting elements ED1, ED2, and ED3 may be physically and easily separated from each other. Accordingly, a current leakage or a driving error between the light emitting areas PXA-R, PXA-G, and PXA-B adjacent to each other may be prevented, and each of the light emitting elements ED1, ED2, and ED3 may be driven independently.

In particular, since the first light emitting patterns EP1 are patterned without masks that are in contact with components in the display area DA (refer to FIG. 1B), a defective rate of the display panel DP may be reduced, and a process reliability of the display panel DP may be improved. As the light emitting patterns are patterned without the support spacer protruding from the barrier wall PW, the size of the light emitting areas PXA-R, PXA-G, and PXA-B may be reduced, and the high resolution of the display panel DP may be implemented.

In some aspects, when manufacturing a large-sized display panel DP, a process cost may be reduced by omitting a production of a large-sized mask, and the display panel DP with improved process reliability may be provided because the display panel DP is not affected by defects that may occur in the large-sized mask. The described herein regarding the first light emitting patterns EP1 may be equally applied to the second and third light emitting patterns EP2 and EP3.

The thin film encapsulation layer TFE may include lower encapsulation inorganic patterns LIL1, LIL2, and LIL3, common inorganic layers CLIL1, CLIL2, and CLIL3, the encapsulation organic layer OL, and the upper encapsulation inorganic layer UIL.

The lower encapsulation inorganic patterns LIL1, LIL2, and LIL3 may include a first lower encapsulation inorganic pattern LIL1 covering the first light emitting element ED1, a second lower encapsulation inorganic pattern LIL2 covering the second light emitting element ED2, and a third lower encapsulation inorganic pattern LIL3 covering the third light emitting element ED3. The first, second, and third lower encapsulation inorganic patterns LIL1, LIL2, and LIL3 may overlap the first, second, and third light emitting openings OP1-E, OP2-E, and OP3-E, respectively. The first, second, and third lower encapsulation inorganic patterns LIL1, LIL2, and LIL3 may be provided in the form of a pattern and may be spaced apart from each other.

The common inorganic layers CLIL1, CLIL2, and CLIL3 may include a first common inorganic layer CLIL1, a second common inorganic layer CLIL2, and a third common inorganic layer CLIL3. The first common inorganic layer CLIL1 may cover a side surface of the first lower encapsulation inorganic pattern LIL1, the second common inorganic layer CLIL2 may cover a side surface of the second lower encapsulation inorganic pattern LIL2, and the third common inorganic layer CLIL3 may cover a side surface of the third lower encapsulation inorganic pattern LIL3. Upper surfaces of the first, second, and third lower encapsulation inorganic patterns LIL1, LIL2, and LIL3 may not be covered by the first, second, and third common inorganic layers CLIL1, CLIL2, and CLIL3. The first common inorganic layer CLIL1, the second common inorganic layer CLIL2, and the third common inorganic layer CLIL3 may include an inorganic material. As an example, the first common inorganic layer CLIL1, the second common inorganic layer CLIL2, and the third common inorganic layer CLIL3 may include at least one of silicon oxide (SiOₓ), silicon nitride (SiNₓ), and silicon oxynitride (SiON).

The separation area SA may be defined by the barrier wall PW, the first, second, and third lower encapsulation inorganic patterns LIL1, LIL2, and LIL3, and the first, second, and third common inorganic layers CLIL1, CLIL2, and CLIL3. The separation area SA may be an empty area. As an example, the separation area SA may be filled with gas.

The encapsulation organic layer OL may cover the lower encapsulation inorganic patterns LIL1, LIL2, and LIL3 and the common inorganic layers CLIL1, CLIL2, and CLIL3. As an example, the encapsulation organic layer OL may cover the upper surface of the first lower encapsulation inorganic pattern LIL1, the upper surface of the second lower encapsulation inorganic pattern LIL2, the upper surface of the third lower encapsulation inorganic pattern LIL3, the first common inorganic layer CLIL1, the second common inorganic layer CLIL2, and the third common inorganic layer CLIL3. The encapsulation organic layer OL may be spaced apart from the separation area SA. The upper encapsulation inorganic layer UIL may be disposed on the encapsulation organic layer OL.

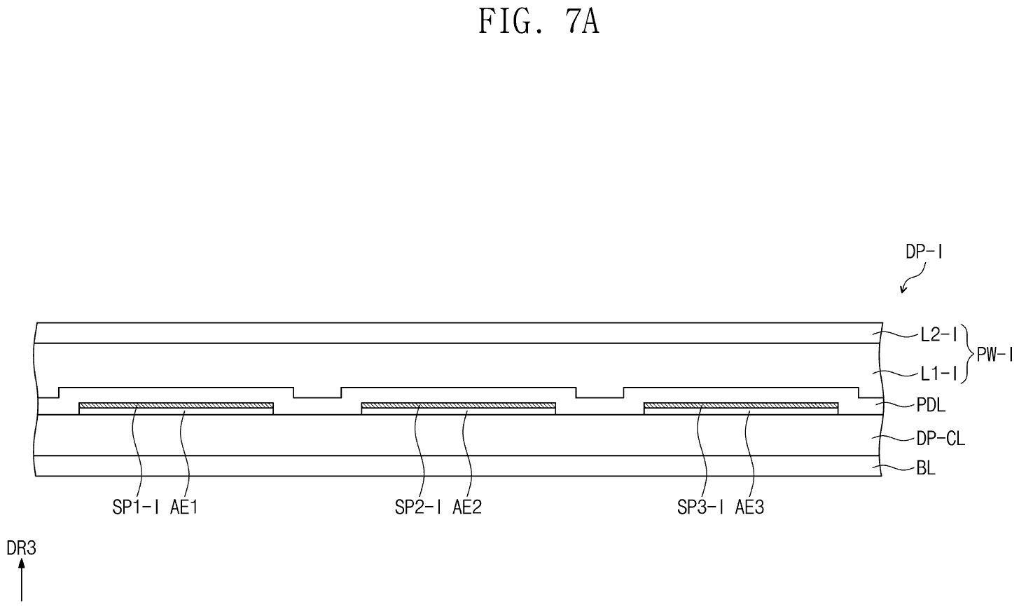

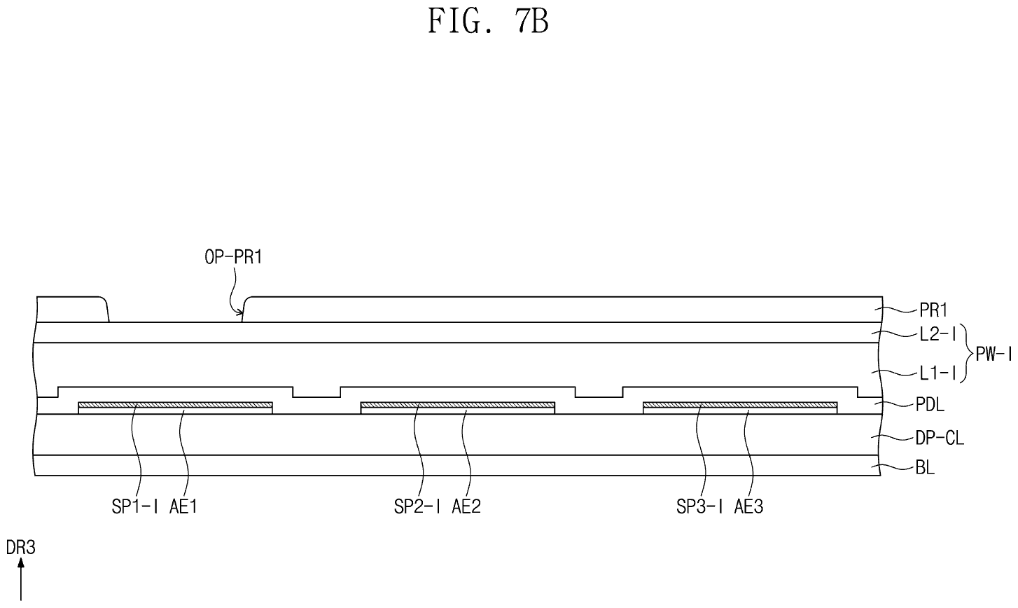

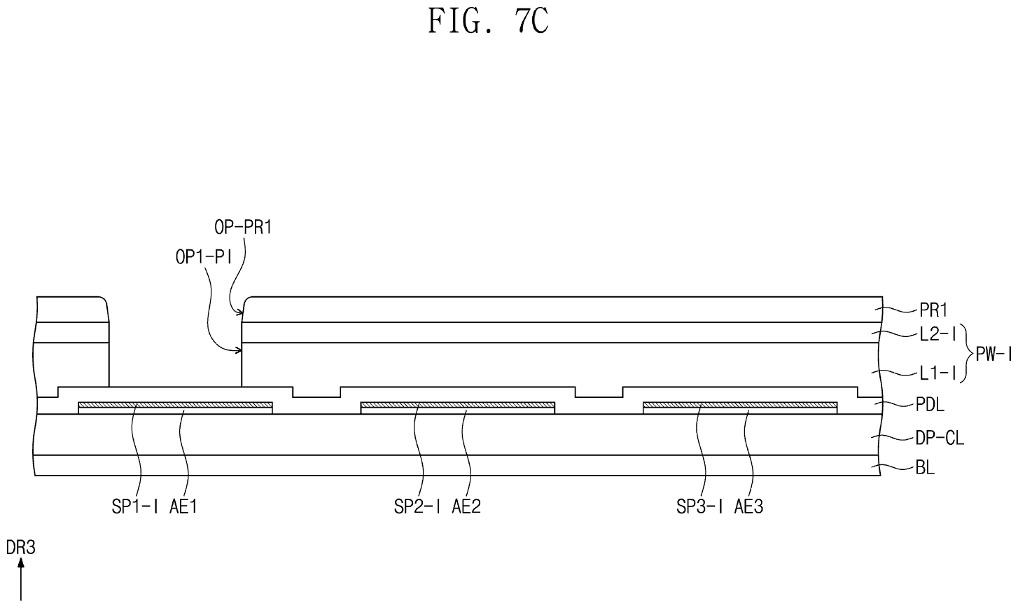

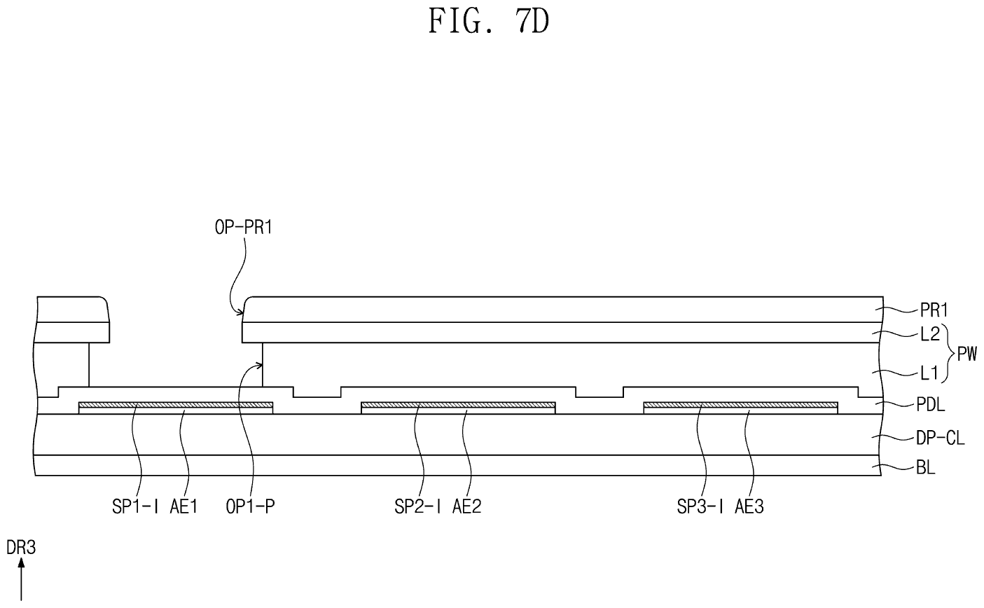

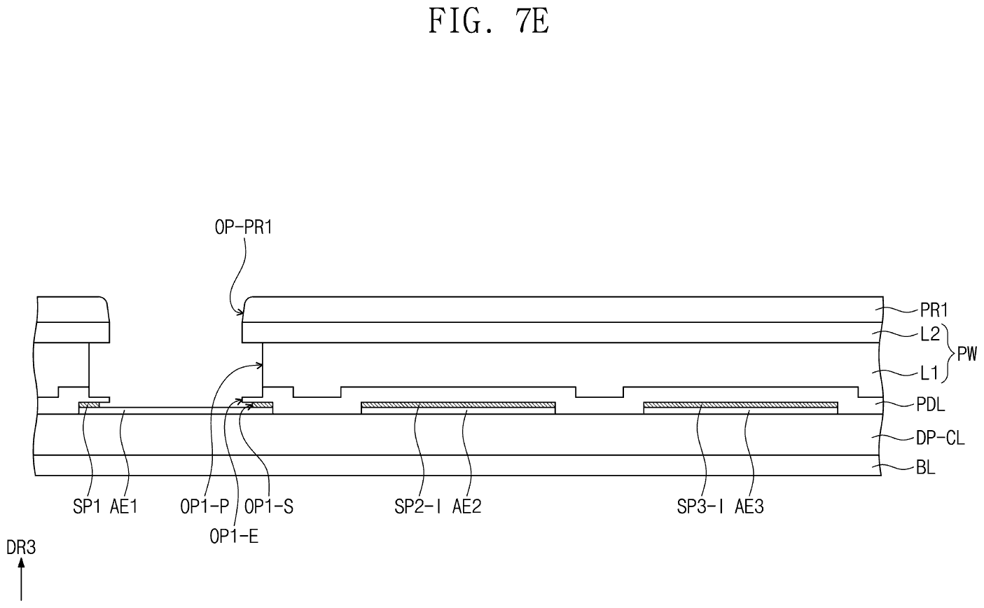

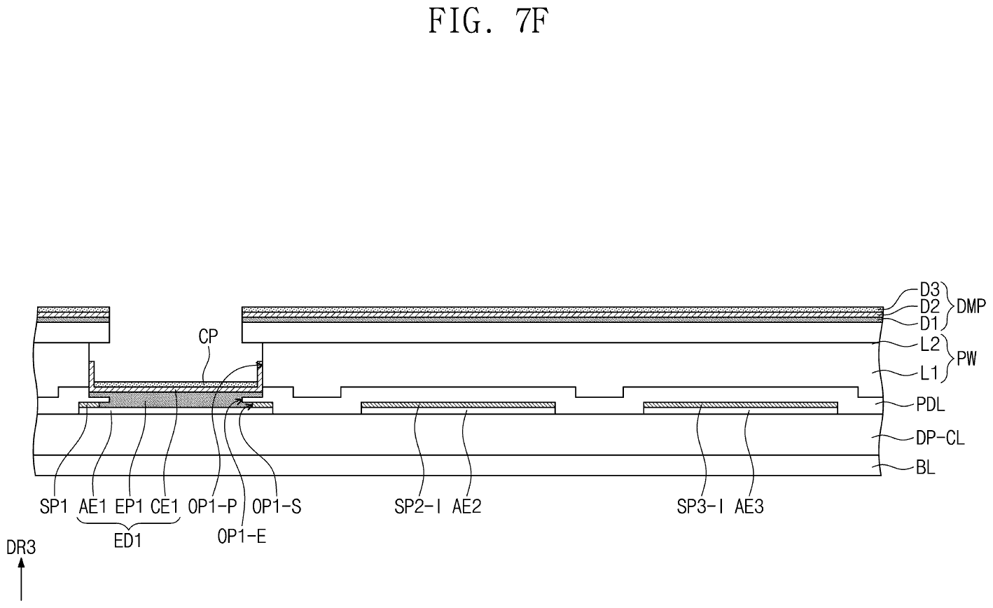

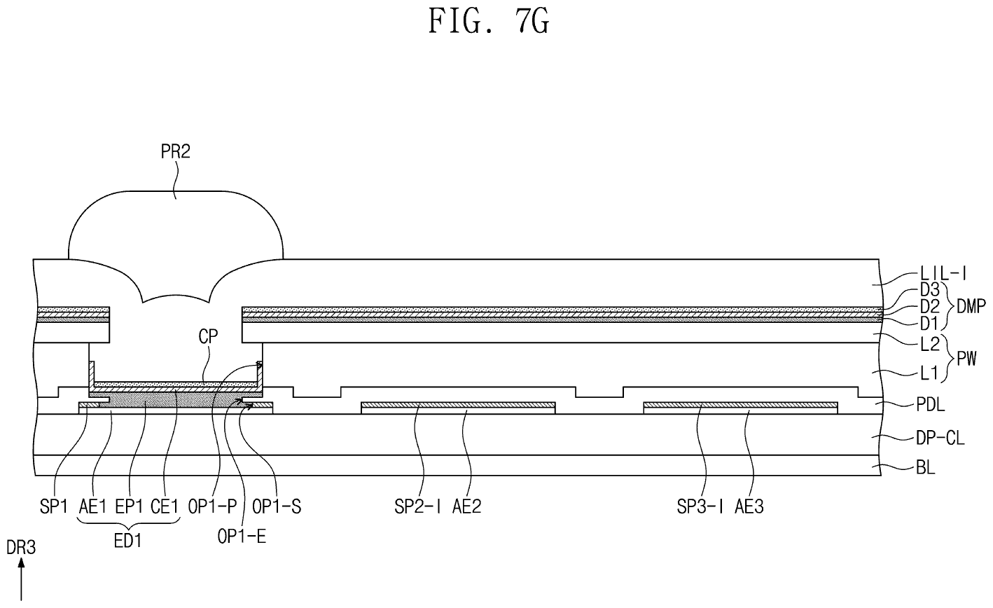

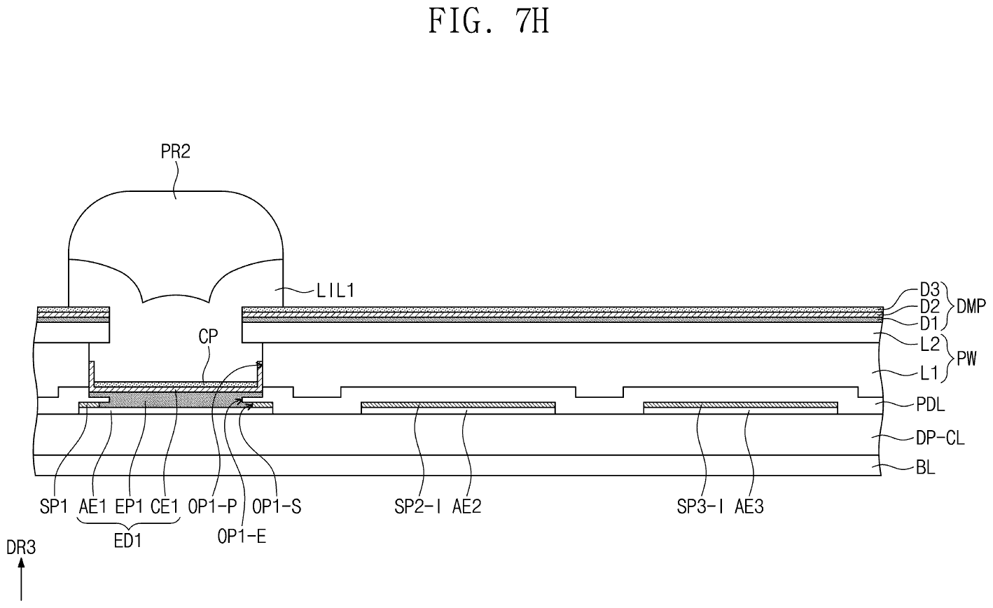

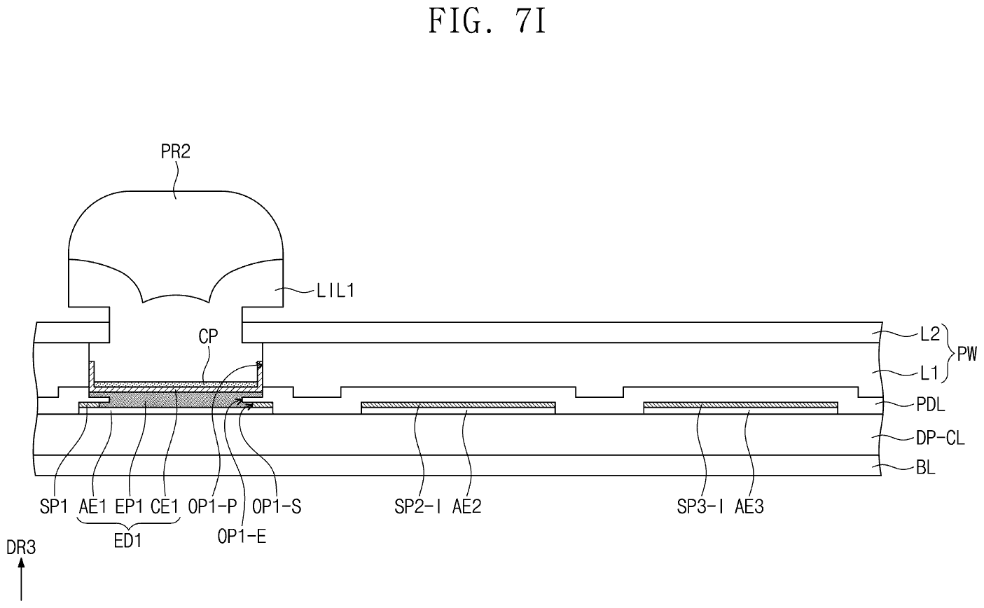

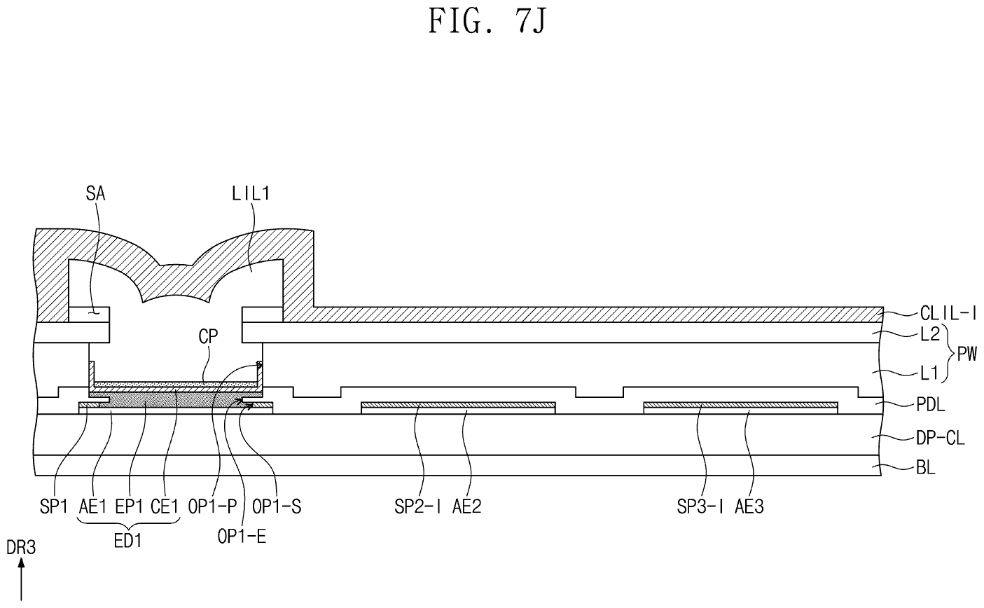

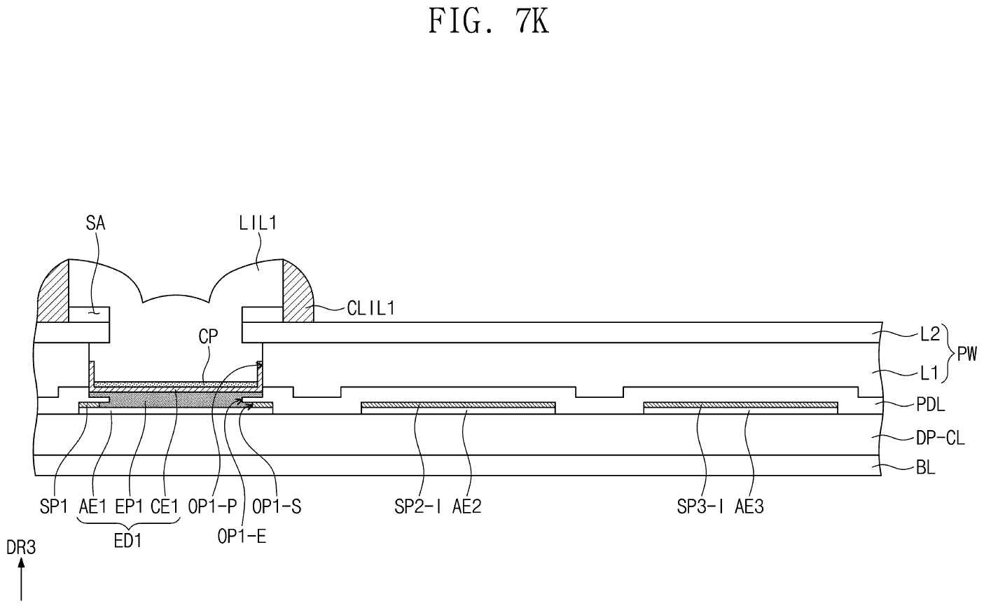

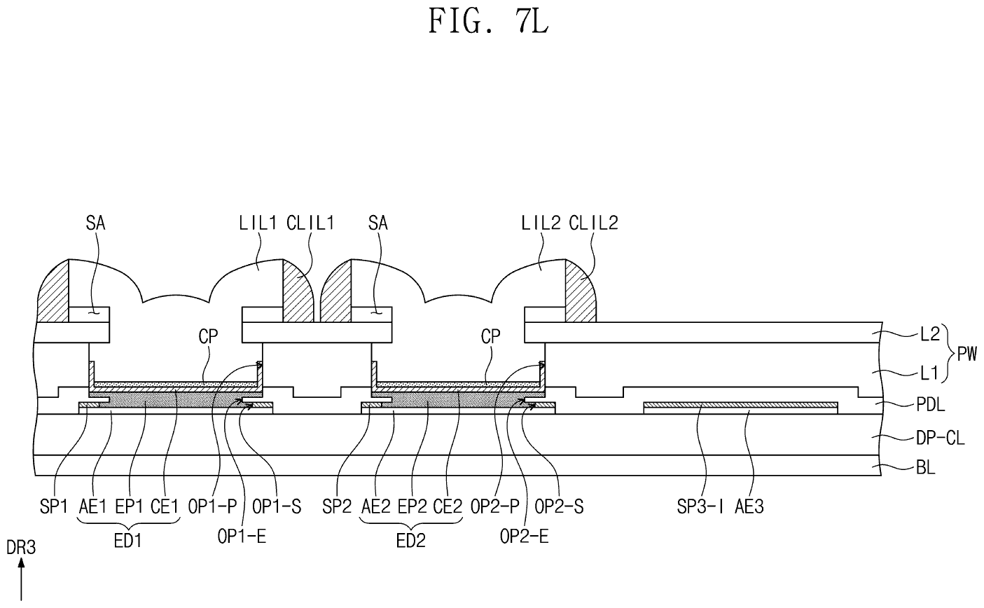

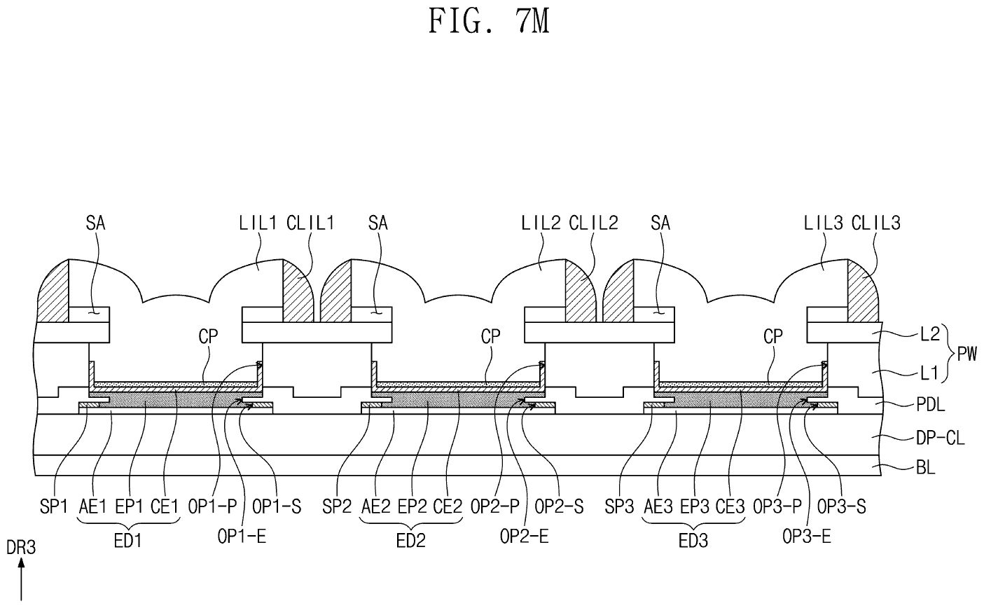

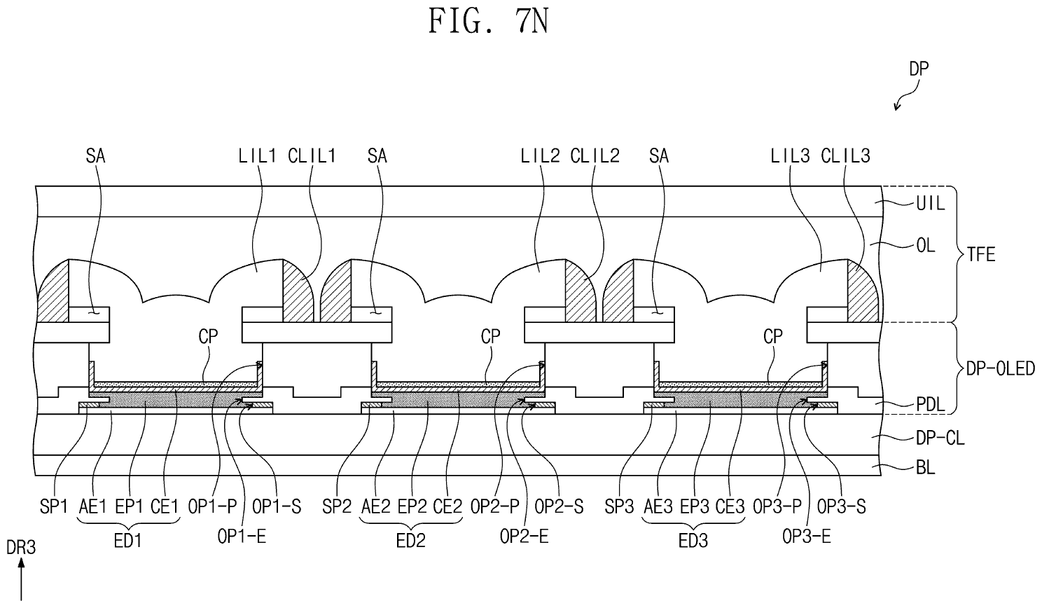

FIGS. 7A to 7N are cross-sectional views illustrating a method of manufacturing the display panel according to an embodiment of the present disclosure. In FIGS. 7A to 7N, the same/similar reference numerals denote the same/similar elements in FIGS. 1 to 6, and thus, detailed descriptions of the same/similar elements will be omitted.

In the descriptions of the method and processes herein, the operations may be performed in a different order than the order shown and/or described, or the operations may be performed in different orders or at different times. Certain operations may also be left out, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

The method of manufacturing the display panel may include providing a preliminary display panel including the base layer, the pixel definition layer disposed on the base layer, and a preliminary barrier wall disposed on the pixel definition layer, forming the barrier wall from the preliminary barrier wall, wherein the barrier wall opening is defined in the barrier wall, etching the pixel definition layer, wherein etching the pixel definition layer forms the light emitting opening overlapping the barrier wall opening, forming the light emitting element including the anode, the light emitting pattern, and the cathode in the light emitting opening and the barrier wall opening, forming the lower encapsulation inorganic pattern covering the light emitting element, depositing a preliminary common inorganic layer covering the lower encapsulation inorganic pattern, and etching a portion of the preliminary common inorganic layer, which overlaps the barrier wall opening, wherein etching the portion of the preliminary common inorganic layer forms the common inorganic layer covering the side surface of the lower encapsulation inorganic pattern.

Hereinafter, the method of forming the three light emitting elements ED1, ED2, and ED3, the lower encapsulation inorganic patterns LIL1, LIL2, and LIL3 respectively covering the light emitting elements ED1, ED2, and ED3, the common inorganic layers CLIL1, CLIL2, and CLIL3, the encapsulation organic layer OL, and the upper encapsulation inorganic layer UIL will be described with reference to FIGS. 7A to 7N. The display panel DP formed through processes illustrated in FIGS. 7A to 7N may correspond to the display panel DP of FIG. 6.

Referring to FIG. 7A, the method of manufacturing the display panel may include the providing of the preliminary display panel DP-I. In the present embodiment, the preliminary display panel DP-I may include the base layer BL, the circuit element layer DP-CL, the first, second, and third anodes AE1, AE2, and AE3, first, second, and third sacrificial layers SP1-I, SP2-I, and SP3-I, the pixel definition layer PDL, and the preliminary barrier wall PW-I. The preliminary barrier wall PW-I may include a first preliminary barrier wall layer L1-I and a second preliminary barrier wall layer L2-I.

The circuit element layer DP-CL may be formed by a conventional circuit element manufacturing method that forms the insulating layer, the semiconductor layer, and the conductive layer by a coating or depositing process and selectively patterns the insulating layer, the semiconductor layer, and the conductive layer by a photolithography process and an etching process to form the semiconductor pattern, the conductive pattern, and the signal line.

The first anode AE1 and the first sacrificial layer SP1-I may be formed through the same patterning process, the second anode AE2 and the second sacrificial layer SP2-I may be formed through the same patterning process, and the third anode AE3 and the third sacrificial layer SP3-I may be formed through the same patterning process. The pixel definition layer PDL may be disposed on the base layer BL. The pixel definition layer PDL may cover the first, second, and third anodes AE1, AE2, and AE3 and the first, second, and third sacrificial layers SP1-I, SP2-I, and SP3-I.

The first preliminary barrier wall layer L1-I may be disposed on the pixel definition layer PDL, and the second preliminary barrier wall layer L2-I may be disposed on the first preliminary barrier wall layer L1-I. The first preliminary barrier wall layer L1-I and the second preliminary barrier wall layer L2-I may be formed by depositing a conductive material. The first preliminary barrier wall layer L1-I may include aluminum (Al) and the second preliminary barrier wall layer L2-I may include titanium (Ti), however, materials for the first preliminary barrier wall layer L1-I and the second preliminary barrier wall layer L2-I should not be limited thereto or thereby. As an example, the first preliminary barrier wall layer L1-I and the second preliminary barrier wall layer L2-I may include metal, transparent conductive oxide (TCO), or a combination thereof. As an example, the metal may include gold (Au), silver (Ag), aluminum (Al), magnesium (Mg), lithium (Li), molybdenum (Mo), titanium (Ti), copper (Cu), or an alloy. The transparent conductive oxide (TCO) may include indium tin oxide (ITO), indium zinc oxide (IZO), zinc oxide, indium oxide, indium gallium oxide, indium gallium zinc oxide (IGZO), or aluminum zinc oxide.

Referring to FIG. 7B, the method of manufacturing the display panel may include forming a first photoresist layer PR1 on the preliminary barrier wall PW-I. The first photoresist layer PR1 may be formed by forming a preliminary photoresist layer on the preliminary barrier wall PW-I and patterning the preliminary photoresist layer using a photomask. Through the patterning process, a first photo opening OP-PR1 may be formed through the first photoresist layer PR1. The first photo opening OP-PR1 may overlap the first anode AE1.

Referring to FIGS. 7C and 7D, the method of manufacturing the display panel may include the forming of the barrier wall PW from the preliminary barrier wall PW-I. The first barrier wall opening (or the barrier wall opening) OP1-P may be defined in the barrier wall PW. The forming of the barrier wall PW may include etching the first preliminary barrier wall layer L1-I and the second preliminary barrier wall layer L2-I, and the etching may define or form the first barrier wall opening OP1-P through each of the first barrier wall layer L1 and the second barrier wall layer L2.

As illustrated in FIG. 7C, the first preliminary barrier wall layer L1-I and the second preliminary barrier wall layer L2-I may be dry-etched (hereinafter, referred to as a first dry etching process) using the first photoresist layer PR1 as a mask. Portions of the preliminary barrier wall PW-I, which do not overlap the first photoresist layer PR1, may be etched and removed. As an example, removing the portions overlapping the first photo opening OP-PRI may form a first preliminary barrier wall opening OPI-PI.

The first dry etching process may be performed in an etching environment where the first preliminary barrier wall layer L1-I and the second preliminary barrier wall layer L2-I have the same etch selectivity as or similar etch selectivity to each other. Accordingly, an inner side surface of the first preliminary barrier wall layer L1-I, which defines the first preliminary barrier wall opening OP1-PI, may be substantially aligned with an inner side surface of the second preliminary barrier wall layer L2-I, which defines the first preliminary barrier wall opening OPI-PI.

As illustrated in FIG. 7D, the first preliminary barrier wall layer L1-I (refer to FIG. 7C) may be wet-etched (hereinafter, referred to as a second wet etching process) using the first photoresist layer PR1 as a mask. Therefore, portions of the first preliminary barrier wall layer L1-I may be etched, and the first barrier wall opening OP1-P may be formed. The first barrier wall opening OP1-P may overlap the first anode AE1.

The second wet etching process may be performed in an etching environment where the etch selectivity between the first preliminary barrier wall layer L1-I and the second preliminary barrier wall layer L2-I (refer to FIG. 7C) is high. Accordingly, inner side surfaces of the barrier wall PW, which define the barrier wall openings OP1-P, OP2-P, and OP3-P (refer to FIG. 7M), may have the undercut shape when viewed in the cross-section. In detail, since an etch rate of the first preliminary barrier wall layer L1-I with respect to an etching solution is greater than an etch rate of the second preliminary barrier wall layer L2-I with respect to the etching solution, the first preliminary barrier wall layer L1-I may be mainly etched. Therefore, the first inner side surface of the first barrier wall layer L1 may be more inwardly recessed than the second inner side surface of the second barrier wall layer L2. The tip portion may be formed in the barrier wall PW by the portion of the second barrier wall layer L2, which protrudes more than the first barrier wall layer L1.

Referring to FIG. 7E, the method of manufacturing the display panel may include the etching of the pixel definition layer PDL to form the first light emitting opening (or the light emitting opening) OP1-E overlapping the first barrier wall opening (or the barrier wall opening) OP1-P.

The pixel definition layer PDL may be dry-etched using the first photoresist layer PR1 and the barrier wall PW (e.g., the second barrier wall layer L2) as a mask. A portion of the pixel definition layer PDL, which does not overlap the first photoresist layer PR1 and the barrier wall PW, may be removed. As a result, the first light emitting opening (or the light emitting opening) OP1-E may be formed through the pixel definition layer PDL and overlap the first barrier wall opening (or the barrier wall opening) OP1-P.

In some aspects, the method of manufacturing the display panel may include etching the first sacrificial layer SP1-I (refer to FIG. 7D) to form the first sacrificial pattern SP1 provided with the first sacrificial opening OP1-S defined through the first sacrificial pattern SP1 to overlap the first light emitting opening OP1-E. For example, etching the first sacrificial layer SP1-I may form the first sacrificial pattern SP1 and the first sacrificial opening OP1-S defined in the first sacrificial pattern SP1, and the first sacrificial opening OP1-S may overlap the first light emitting opening OP1-E.

The first sacrificial layer SP1-I may be wet-etched using the first photoresist layer PR1 and the barrier wall PW (e.g., the second barrier wall layer L2) as a mask. A portion of the first sacrificial layer SP1-I, which does not overlap the first photoresist layer PR1 and the barrier wall PW, may be etched and removed. As a result, the first sacrificial pattern SP1 may be formed from the first sacrificial layer SP1-I. The first sacrificial opening OP1-S may be formed through the first sacrificial pattern SP1 and overlap the first light emitting opening OP1-E.

The etching of the first sacrificial pattern SP1 may be performed in an environment where an etch selectivity between the first sacrificial pattern SP1 and the first anode AE1 is high, and thus, etching of the first anode AE1 may be prevented. That is, as the first sacrificial pattern SP1 having an etch rate higher than an etch rate of the first anode AE1 is disposed between the pixel definition layer PDL and the first anode AE1, the first anode AE1 may be prevented from being etched and damaged in the etching process of the first sacrificial pattern SP1.

Referring to FIG. 7F, after the removing of the first photoresist layer PR1 (refer to FIG. 7E), the method of manufacturing the display panel may include forming the first light emitting element (or the light emitting element) ED1 including the first anode (or the anode) AE1, the first light emitting pattern (or the light emitting pattern) EP1, and the first cathode (or the cathode) CEL in the first light emitting opening (or the light emitting opening) OP1-E and the first barrier wall opening (or the barrier wall opening) OP1-P.

The forming of the first light emitting element ED1 may include forming the first light emitting pattern EP1 and forming the first cathode CEL. In some aspects, the forming of the first light emitting element (or the light emitting element) ED1 may include forming a dummy layer DMP including the same material as the first light emitting pattern (or the light emitting pattern) EP1 and the first cathode (or the cathode) CEL on the barrier wall PW.

The forming of the first light emitting pattern EP1 may include depositing the light emitting layer. As an example, the forming of the first light emitting pattern EP1 may include thermally depositing the light emitting layer. The light emitting layer may be separated by the tip portion formed in the barrier wall PW and may be deposited in the first barrier wall opening OP1-P and on the barrier wall PW. The light emitting layer formed in the first barrier wall opening OP1-P may form the first light emitting pattern EP1, and the light emitting layer formed on the barrier wall PW may form a first dummy layer D1. That is, the first light emitting pattern EP1 may be formed on the first anode AE1 and overlap the first barrier wall opening OP1-P, and the first light emitting pattern EP1 may cover the first anode AE1 and the pixel definition layer PDL.

The first dummy layer D1 formed in the forming of the first light emitting pattern EP1 may include an organic material. As an example, the first dummy layer D1 may include the same material as the first light emitting pattern EP1. The first dummy layer D1 and the first light emitting pattern EP1 may be substantially simultaneously formed through a single process, and the first dummy layer D1 may be formed separately from the first light emitting pattern EP1 due to the undercut shape of the barrier wall PW. It is to be understood that the phrase “may include the same material as” may be equivalent to “may be formed of the same material as.”

The forming of the first cathode CE1 may include depositing a cathode layer. As an example, the forming of the first cathode CE1 may include sputtering the cathode layer. The cathode layer may be separated by the tip portion of the barrier wall PW and may be deposited in the first barrier wall opening OP1-P and on the barrier wall PW. The cathode layer formed in the first barrier wall opening OP1-P may form the first cathode CE1, and the cathode layer formed on the barrier wall PW may form a second dummy layer D2. That is, the first cathode CE1 may be formed on the first light emitting pattern EP1 and overlap the first barrier wall opening OP1-P, and the first cathode CE1 may cover the first light emitting pattern EP1. In some aspects, the first cathode CE1 may be in contact with the inner side surface of the first barrier wall layer L1 and may extend along the inner side surface of the first barrier wall layer L1.

The second dummy layer D2 formed in the forming of the first cathode CE1 may include the conductive material. As an example, the second dummy layer D2 may include the same material as the first cathode CE1. The second dummy layer D2 and the first cathode CE1 may be substantially simultaneously formed through a single process, and the second dummy layer D2 may be formed separately from the first cathode CE1 due to the undercut shape of the barrier wall PW.

The first anode AE1, the first light emitting pattern EP1, and the first cathode CE1 may be sequentially stacked in the third direction DR3. The first anode AE1, the first light emitting pattern EP1, and the first cathode CE1 may form the first light emitting element ED1.

The method of manufacturing the display panel may further include forming the capping pattern CP. The forming of the capping pattern CP may include depositing a capping pattern layer. The capping pattern layer may be separated by the tip portion formed in the barrier wall PW and may be deposited in the first barrier wall opening OP1-P and on the barrier wall PW. The capping pattern layer formed in the first barrier wall opening OP1-P may form the capping pattern CP, and the capping pattern layer formed on the barrier wall PW may form a third dummy layer D3.

The third dummy layer D3 formed in the forming of the capping pattern CP may include a conductive material. As an example, the third dummy layer D3 may include the same material as the capping pattern CP. The third dummy layer D3 and the capping pattern CP may be substantially simultaneously formed through a single process, and the third dummy layer D3 may be formed separately from the capping pattern CP due to the undercut shape of the barrier wall PW. According to an embodiment, the process of forming the capping pattern CP and the third dummy layer D3 may be omitted.

The first dummy layer D1, the second dummy layer D2, and the third dummy layer D3 may be sequentially stacked in the third direction DR3. The first dummy layer D1, the second dummy layer D2, and the third dummy layer D3 may form the dummy layer DMP.

Referring to FIG. 7G, the method of manufacturing the display panel may include forming the first lower encapsulation inorganic pattern (or the lower encapsulation inorganic pattern) LIL1 covering the first light emitting element (or the light emitting element) ED1.

The forming of the first lower encapsulation inorganic pattern LIL1 may include depositing a first lower encapsulation inorganic layer LIL-I covering an inner portion of the first barrier wall opening (or the barrier wall opening) OP1-P and an upper portion of the barrier wall PW. The first lower encapsulation inorganic layer LIL-I may be formed by a deposition process. The first lower encapsulation inorganic layer LIL-I may be formed by a chemical vapor deposition (CVD). The first lower encapsulation inorganic layer LIL-I may be formed such that the first lower encapsulation inorganic layer LIL-I covers the first cathode CE1 (or the capping pattern CP) and the barrier wall PW. A portion of the first lower encapsulation inorganic layer LIL-I may be filled in the first barrier wall opening OP1-P.

Then, the method of manufacturing the display panel may include forming a second photoresist layer PR2. The second photoresist layer PR2 may be formed by forming a preliminary photoresist layer and patterning the preliminary photoresist layer using a photomask. Through the patterning process, the second photoresist layer PR2 may be formed in the form of a pattern corresponding to the first light emitting element ED1.

Referring to FIG. 7H, the forming of the first lower encapsulation inorganic pattern (or the lower encapsulation inorganic pattern) LIL1 may include removing a portion of the first lower encapsulation inorganic layer LIL-I (refer to FIG. 7H), which does not overlap the first light emitting element (or the light emitting element) ED1.

The portion of the first lower encapsulation inorganic layer LIL-I, which does not overlap the first light emitting element ED1, may be dry-etched using the second photoresist layer PR2 as a mask. The portion of the first lower encapsulation inorganic layer LIL-I, which does not overlap the second photoresist layer PR2, may be removed, and the portion of the first lower encapsulation inorganic layer LIL-I, which remains without being etched, may be formed as the first lower encapsulation inorganic pattern LIL1.

Referring to FIG. 7I, the forming of the first lower encapsulation inorganic pattern (or the lower encapsulation inorganic pattern) LIL1 may include removing the dummy layer DMP (refer to FIG. 7H). Among the dummy layers D1, D2, and D3, the second and third dummy layers D2 and D3 may be removed by a wet etch process, and the first dummy layer D1 of the dummy layers D1, D2, and D3 may be removed by a stripper.

Referring to FIG. 7J, the method of manufacturing the display panel may include depositing the preliminary common inorganic layer CLIL-I, such that the preliminary common inorganic layer CLIL-I covers the first lower encapsulation inorganic pattern (or the lower encapsulation inorganic pattern) LIL1, after the removing of the second photoresist layer PR2 (refer to FIG. 7I). The preliminary common inorganic layer CLIL-I may be formed such that the preliminary common inorganic layer CLIL-I covers the upper portion of the barrier wall PW and the first lower encapsulation inorganic pattern LIL1. The preliminary common inorganic layer CLIL-I may include an inorganic material. As an example, the preliminary common inorganic layer CLIL-I may include at least one of silicon oxide (SiOₓ), silicon nitride (SiNₓ), and silicon oxynitride (SiON).

The depositing of the preliminary common inorganic layer CLIL-I may include forming the separation area SA by the barrier wall PW, the first lower encapsulation inorganic pattern (or the lower encapsulation inorganic pattern) LIL1, and the preliminary common inorganic layer CLIL-I. For example, the third portion P3 (refer to FIG. 5) of the first lower encapsulation inorganic pattern LIL1 is spaced apart from the upper surface U_PW (refer to FIG. 5) of the barrier wall PW when viewed in the cross-section, and the preliminary common inorganic layer CLIL-I covers the side surface S_P3 (refer to FIG. 5) of the first lower encapsulation inorganic pattern LIL1, thus forming the separation area SA. The separation area SA may be the empty area. As an example, the separation area SA may be filled with the gas.

Referring to FIG. 7K, the method of manufacturing the display panel may include etching a portion of the preliminary common inorganic layer CLIL-I (refer to FIG. 7K), which overlaps the first barrier wall opening (or the barrier wall opening) OP1-P, to form the first common inorganic layer (or the common inorganic layer) CLIL1 covering the side surface of the first lower encapsulation inorganic pattern (or the lower encapsulation inorganic pattern) LIL1.

The forming of the first common inorganic layer (or the common inorganic layer) CLIL1 may include etching the preliminary common inorganic layer CLIL-I for a set period of time or etching the preliminary common inorganic layer CLIL-I until a specific gas is detected. For example, the method may include terminating the etching of the preliminary common inorganic layer CLIL-I in response to detecting the specific gas.

When the preliminary common inorganic layer CLIL-I and the first lower encapsulation inorganic pattern LIL1 include the same material as each other, the first common inorganic layer CLIL1 may be formed by etching the preliminary common inorganic layer CLIL-I for a set period of time. Aspects of the present disclosure include setting the etching time such that the preliminary common inorganic layer CLIL-I is etched and the first lower encapsulation inorganic pattern LIL1 is not etched.

According to an embodiment, when the preliminary common inorganic layer CLIL-I and the first lower encapsulation inorganic pattern LIL1 include different materials from each other, the first common inorganic layer CLIL1 may be formed by etching the preliminary common inorganic layer CLIL-I until the specific gas is detected. As an example, when the first lower encapsulation inorganic pattern LIL1 includes silicon nitride (SiNₓ) and the preliminary common inorganic layer CLIL-I includes silicon oxide (SiOₓ) or silicon oxynitride (SiON), the first common inorganic layer CLIL1 may be formed by etching the preliminary common inorganic layer CLIL-I until nitrogen gas is sensed. The nitrogen gas may be formed from silicon nitride (SiNₓ) included in the first lower encapsulation inorganic pattern LIL1.

The first common inorganic layer CLIL1 may cover the side surface S_P3 (refer to FIG. 5) of the third portion P3 (refer to FIG. 5) of the first lower encapsulation inorganic pattern LIL1. In other words, the upper surface U_LIL (refer to FIG. 5) of the first lower encapsulation inorganic pattern LIL1 may not be covered by the first common inorganic layer CLIL1.

Referring to FIG. 7L, the method of manufacturing the display panel may include forming the second barrier wall opening OP2-P, the second light emitting opening OP2-E, the second sacrificial opening OP2-S, the second light emitting element ED2, the capping pattern CP, the second lower encapsulation inorganic pattern LIL2, and the second common inorganic layer CLIL2. The processes of forming the second barrier wall opening OP2-P, the second light emitting opening OP2-E, the second sacrificial opening OP2-S, the second light emitting element ED2, the capping pattern CP, the second lower encapsulation inorganic pattern LIL2, and the second common inorganic layer CLIL2 may be substantially the same as the processes of forming the first barrier wall opening OP1-P, the first light emitting opening OP1-E, the first sacrificial opening OP1-S, the first light emitting element ED1, the capping pattern CP, the first lower encapsulation inorganic pattern LIL1, and the first common inorganic layer CLIL1 described with reference to FIGS. 7B to 7K.

Referring to FIG. 7M, the method of manufacturing the display panel may include forming the third barrier wall opening OP3-P, the third light emitting opening OP3-E, the third sacrificial opening OP3-S, the third light emitting element ED3, the capping pattern CP, the third lower encapsulation inorganic pattern LIL3, and the third common inorganic layer CLIL3. The processes of forming the third barrier wall opening OP3-P, the third light emitting opening OP3-E, the third sacrificial opening OP3-S, the third light emitting element ED3, the capping pattern CP, the third lower encapsulation inorganic pattern LIL3, and the third common inorganic layer CLIL3 may be substantially the same as the processes of forming the first barrier wall opening OP1-P, the first light emitting opening OP1-E, the first sacrificial opening OP1-S, the first light emitting element ED1, the capping pattern CP, the first lower encapsulation inorganic pattern LIL1, and the first common inorganic layer CLIL1 described with reference to FIGS. 7B to 7K.

As illustrated in FIGS. 7A to 7M, the method may include forming the second barrier wall opening OP2-P and the second light emitting element ED2, which correspond to the second light emitting area PXA-G (refer to FIG. 6), after forming the first barrier wall opening OP1-P and the first light emitting element ED1, which correspond to the first light emitting area PXA-R (refer to FIG. 6). The method may include then forming the third barrier wall opening OP3-P and the third light emitting element ED3, which correspond to the third light emitting area PXA-B (refer to FIG. 6). However, this is an example, in a manufacturing method of a display panel according to an embodiment, the first, second, and third barrier wall openings OP1-P, OP2-P, and OP3-P corresponding to the first, second, and third light emitting areas PXA-R, PXA-G, and PXA-B may substantially simultaneously formed, and then, the first light emitting element ED1, the second light emitting element ED2, and the third light emitting element ED3 may be formed.

Referring to FIG. 7N, the method of manufacturing the display panel may include forming the encapsulation organic layer OL covering the first, second, and third lower encapsulation inorganic patterns (or the lower encapsulation inorganic pattern) LIL1, LIL2, and LIL3 and the first, second, and third common inorganic layers (or the common inorganic layers) CLIL1, CLIL2, and CLIL3. Since the first, second, and third common inorganic layers CLIL1, CLIL2, and CLIL3 do not cover the upper surfaces of the first, second, and third lower encapsulation inorganic patterns LIL1, LIL2, and LIL3, the encapsulation organic layer OL may be directly in contact with the upper surfaces of the first, second, and third lower encapsulation inorganic patterns LIL1, LIL2, and LIL3. The encapsulation organic layer OL may be spaced apart from the separation areas SA. The encapsulation organic layer OL may be formed by depositing the organic material (i.e., applying a coating including the organic material) through an inkjet method, however, the encapsulation organic layer OL should not be limited thereto or thereby. The encapsulation organic layer OL may provide the flat surface thereon.

In some aspects, the method of manufacturing the display panel may include forming the upper encapsulation inorganic layer UIL to complete the display panel DP. Then, the upper encapsulation inorganic layer UIL may be formed by depositing the inorganic material. Thus, the display panel DP including the base layer BL, the circuit element layer DP-CL, the display element layer DP-OLED, and the thin film encapsulation layer TFE may be formed.

FIG. 8 is a cross-sectional view of a display panel DPa taken along a line I-I′ of FIG. 3. The cross-sectional view of FIG. 8 corresponds to the cross-sectional view of FIG. 5. In FIG. 8, the same/similar reference numerals denote the same/similar elements in FIG. 5, and thus, detailed descriptions of the same/similar elements will be omitted.

Referring to FIG. 8, the display panel DPa may include a base layer BL, a circuit element layer DP-CL, a display element layer DP-OLED, and a thin film encapsulation layer TFEa. The thin film encapsulation layer TFEa may include a lower encapsulation inorganic pattern LIL, an additional encapsulation inorganic pattern ALIL, a common inorganic layer CLILa, an encapsulation organic layer OLa, and an upper encapsulation inorganic layer UIL.

The thin film encapsulation layer TFEa of FIG. 8 may further include the additional encapsulation inorganic pattern ALIL compared to the thin film encapsulation layer TFE of FIG. 5. The additional encapsulation inorganic pattern ALIL may be disposed between the lower encapsulation inorganic pattern LIL and the encapsulation organic layer OLa. The lower encapsulation inorganic pattern LIL may have an undercut shape with respect to the additional encapsulation inorganic pattern ALIL, and the additional encapsulation inorganic pattern ALIL may include a tip portion TP protruding further than the lower encapsulation inorganic pattern LIL.

The lower encapsulation inorganic pattern LIL and the common inorganic layer CLILa may include silicon nitride (SiNₓ), and the additional encapsulation inorganic pattern ALIL may include O-rich silicon nitride (SiNₓ) or silicon oxide (SiOₓ), however, this is an example. Materials for the lower encapsulation inorganic pattern LIL, the common inorganic layer CLILa, and the additional encapsulation inorganic pattern ALIL should not be particularly limited as long as the lower encapsulation inorganic pattern LIL, the common inorganic layer CLILa, and the additional encapsulation inorganic pattern ALIL have the structural characteristics of the present disclosure.

The common inorganic layer CLILa may cover a side surface of the lower encapsulation inorganic pattern LIL and may be in contact with a lower surface of the additional encapsulation inorganic pattern ALIL, which defines the tip portion TP. The encapsulation organic layer OLa may cover the additional encapsulation inorganic pattern ALIL and the common inorganic layer CLILa.

Referring to FIGS. 7G and 8, a method of manufacturing the display panel DPa may further include forming the additional encapsulation inorganic pattern ALIL on the lower encapsulation inorganic pattern LIL. The forming of the additional encapsulation inorganic pattern ALIL may include depositing an additional encapsulation inorganic layer on a lower encapsulation inorganic layer LIL-I, forming a second photoresist layer PR2 on the additional encapsulation inorganic layer, removing a portion of a first lower encapsulation inorganic layer LIL-I (refer to LIL-I of FIG. 7G) and a portion of the additional encapsulation inorganic layer, which do not overlap a first light emitting element ED1, and removing a dummy layer DMP.

In the removing of the portion of the first lower encapsulation inorganic layer LIL-I and the portion of the additional encapsulation inorganic layer, which do not overlap the first light emitting element ED1, the first lower encapsulation inorganic layer LIL-I may be etched more than the additional encapsulation inorganic layer. As a result, the lower encapsulation inorganic pattern LIL having the undercut shape with respect to the additional encapsulation inorganic pattern ALIL may be formed, and the additional encapsulation inorganic pattern ALIL having the tip portion TP protruding further than the lower encapsulation inorganic pattern LIL may be formed.

Then, the method of manufacturing the display panel DPa may further include forming the common inorganic layer CLILa that covers the side surface of the lower encapsulation inorganic pattern LIL and is in contact with the lower surface of the additional encapsulation inorganic pattern ALIL.

FIG. 9 is a cross-sectional view of a display panel DPb taken along a line I-I′ of FIG. 3. The cross-sectional view of FIG. 9 corresponds to the cross-sectional view of FIG. 5. In FIG. 9, the same/similar reference numerals denote the same/similar elements in FIG. 5, and thus, detailed descriptions of the same/similar elements will be omitted.

Referring to FIG. 9, the display panel DPb may include a base layer BL, a circuit element layer DP-CL, a display element layer DP-OLED, and a thin film encapsulation layer TFEb. The thin film encapsulation layer TFEb may include a lower encapsulation inorganic pattern LIL, an additional encapsulation inorganic pattern ALILa, a common inorganic layer CLILb, an encapsulation organic layer OLb, and an upper encapsulation inorganic layer UIL.

The thin film encapsulation layer TFEb of FIG. 9 may further include an additional encapsulation inorganic pattern ALILa compared to the thin film encapsulation layer TFE of FIG. 5. The additional encapsulation inorganic pattern ALILa may be disposed between the lower encapsulation inorganic pattern LIL and the encapsulation organic layer OLb. As illustrated in FIG. 9, a side surface of the additional encapsulation inorganic pattern ALILa may be aligned with a side surface of the lower encapsulation inorganic pattern LIL.

The lower encapsulation inorganic pattern LIL and the common inorganic layer CLILb may include silicon nitride (SiNₓ), and the additional encapsulation inorganic pattern ALILa may include O-rich silicon nitride (SiNₓ) or silicon oxide (SiOₓ), however, this is an example. Materials for the lower encapsulation inorganic pattern LIL, the common inorganic layer CLILb, and the additional encapsulation inorganic pattern ALILa should not be particularly limited as long as the lower encapsulation inorganic pattern LIL, the common inorganic layer CLILb, and the additional encapsulation inorganic pattern ALILb have the structural characteristics of the present disclosure.

The common inorganic layer CLILb may be in contact with the side surface of the lower encapsulation inorganic pattern LIL and the side surface of the additional encapsulation inorganic pattern ALILa. FIG. 9 illustrates the common inorganic layer CLILb that covers the side surface of the lower encapsulation inorganic pattern LIL and a portion of the side surface of the additional encapsulation inorganic pattern ALILa as a representative example, however, the present disclosure should not be limited thereto or thereby. As an example, the common inorganic layer CLILb may entirely cover the side surface of the lower encapsulation inorganic pattern LIL and the side surface of the additional encapsulation inorganic pattern ALILa.

Referring to FIGS. 7G and 9, a method of manufacturing the display panel DPb may further include forming the additional encapsulation inorganic pattern ALILa on the lower encapsulation inorganic pattern LIL. The forming of the additional encapsulation inorganic pattern ALILa may include depositing an additional encapsulation inorganic layer on a lower encapsulation inorganic layer LIL-I (refer to FIG. 7G), forming a second photoresist layer PR2 on the additional encapsulation inorganic layer, removing a portion of the first lower encapsulation inorganic layer LIL-I and a portion of the additional encapsulation inorganic layer, which do not overlap a first light emitting element ED1, and removing a dummy layer DMP.

The removing of the portion of the first lower encapsulation inorganic layer LIL-I (refer to FIG. 7H) and the portion of the additional encapsulation inorganic layer, which do not overlap the first light emitting element ED1, may be performed in an etching environment where the first lower encapsulation inorganic layer LIL-I and the additional encapsulation inorganic layer have substantially the same etch selectivity. Accordingly, the side surface of the first lower encapsulation inorganic pattern LIL may be substantially aligned with the side surface of the additional encapsulation inorganic pattern ALILa.

The method of manufacturing the display panel DPb may further include forming the common inorganic layer CLILb that covers the side surface of the lower encapsulation inorganic pattern LIL and the side surface of the additional encapsulation inorganic pattern ALILa.

Referring to FIGS. 7K, 8, and 9, when the encapsulation layer TFEa or TFEb includes the additional encapsulation inorganic pattern ALIL or ALILa, even though the lower encapsulation inorganic pattern LIL and the common inorganic layer CLILa or CLILb include the same material, the common inorganic layer CLILa or CLILb may be formed by etching the preliminary common inorganic layer CLIL-I until a specific gas is detected. As an example, when the lower encapsulation inorganic pattern LIL and the preliminary common inorganic layer CLIL-I include silicon nitride (SiNₓ) and the additional encapsulation inorganic pattern ALIL or ALILa includes silicon oxide (SiOₓ) or silicon oxynitride (SiON), the common inorganic layer ALIL or ALILa may be formed by etching the preliminary common inorganic layer CLIL-I until the specific gas included in the additional encapsulation inorganic pattern ALIL or ALILa is detected.

Although the embodiments of the present disclosure have been described, it is understood that the present disclosure should not be limited to the example embodiments but various changes and modifications can be made by one ordinary skilled in the art within the spirit and scope of the present disclosure as hereinafter claimed. Therefore, the disclosed subject matter should not be limited to any single embodiment described herein, and the scope of the present inventive concept shall be determined according to the attached claims.

What is claimed is:

1. A display panel comprising:
a base layer;
a pixel definition layer disposed on the base layer, wherein a light emitting opening is defined in the pixel definition layer;
a barrier wall disposed on the pixel definition layer, wherein a barrier wall opening defined in the barrier wall overlaps the light emitting opening;
a light emitting element disposed in the light emitting opening and the barrier wall opening and comprising an anode, a light emitting pattern, and a cathode that is in contact with the barrier wall;
a lower encapsulation inorganic pattern comprising a first portion disposed in the barrier wall opening and covering the light emitting element, a second portion extending from the first portion in a thickness direction of the base layer, and a third portion extending from the second portion and spaced apart from an upper surface of the barrier wall when viewed in a cross-section; and
a common inorganic layer covering a side surface of the third portion of the lower encapsulation inorganic pattern.

2. The display panel of claim 1, wherein the upper surface of the barrier wall, the second portion of the lower encapsulation inorganic pattern, the third portion of the lower encapsulation inorganic pattern, and the common inorganic layer define a separation area.

3. The display panel of claim 2, wherein the separation area surrounds the second portion of the lower encapsulation inorganic pattern when viewed in a plane.

4. The display panel of claim 2, further comprising an encapsulation organic layer that covers the lower encapsulation inorganic pattern and the common inorganic layer,
wherein the encapsulation organic layer is directly in contact with an upper surface of the lower encapsulation inorganic pattern.

5. The display panel of claim 4, wherein the separation area is spaced apart from the encapsulation organic layer.

6. The display panel of claim 4, further comprising an additional encapsulation inorganic pattern disposed between the lower encapsulation inorganic pattern and the encapsulation organic layer.

7. The display panel of claim 6, wherein:
the lower encapsulation inorganic pattern has an undercut shape with respect to the additional encapsulation inorganic pattern, and
the additional encapsulation inorganic pattern comprises a tip portion that protrudes more than the lower encapsulation inorganic pattern.

8. The display panel of claim 7, wherein the common inorganic layer is in contact with a lower surface of the additional encapsulation inorganic pattern defining the tip portion.

9. The display panel of claim 6, wherein a side surface of the lower encapsulation inorganic pattern is aligned with a side surface of the additional encapsulation inorganic pattern.

10. The display panel of claim 9, wherein the common inorganic layer is in contact with the side surface of the lower encapsulation inorganic pattern and the side surface of the additional encapsulation inorganic pattern.

11. The display panel of claim 1, wherein the common inorganic layer comprises an inorganic material.

12. The display panel of claim 1, wherein the common inorganic layer comprises at least one of silicon oxide (SiOₓ), silicon nitride (SiNₓ), and silicon oxynitride (SiON).

13. A method of manufacturing a display panel, comprising:
providing a preliminary display panel comprising a base layer, a pixel definition layer disposed on the base layer, and a preliminary barrier wall disposed on the pixel definition layer;
forming a barrier wall from the preliminary barrier wall, wherein a barrier wall opening is defined in the barrier wall;
etching the pixel definition layer, wherein etching the pixel definition layer forms a light emitting opening overlapping the barrier wall opening;
forming a light emitting element comprising an anode, a light emitting pattern, and a cathode in the light emitting opening and the barrier wall opening;
forming a lower encapsulation inorganic pattern covering the light emitting element;
depositing a preliminary common inorganic layer covering the lower encapsulation inorganic pattern; and
etching a portion of the preliminary common inorganic layer, which overlaps the barrier wall opening, wherein etching the portion of the preliminary common inorganic layer forms a common inorganic layer covering a side surface of the lower encapsulation inorganic pattern.

14. The method of claim 13, wherein:
the forming of the light emitting element comprises forming a dummy layer comprising a same material as the light emitting pattern and the cathode on the barrier wall, and
the forming of the lower encapsulation inorganic pattern covering the light emitting element comprises:
depositing a lower encapsulation inorganic layer covering an inner portion of the barrier wall opening and an upper portion of the barrier wall;
removing a portion of the lower encapsulation inorganic layer, wherein the portion of the lower encapsulation inorganic layer does not overlap the light emitting element; and
removing the dummy layer.

15. The method of claim 13, wherein the depositing of the preliminary common inorganic layer comprises forming a separation area based on the barrier wall, the lower encapsulation inorganic pattern, and the preliminary common inorganic layer.

16. The method of claim 13, further comprising forming an encapsulation organic layer that covers the lower encapsulation inorganic pattern and the common inorganic layer,
wherein the encapsulation organic layer is directly in contact with an upper surface of the lower encapsulation inorganic pattern.

17. The method of claim 13, further comprising forming an additional encapsulation inorganic pattern on the lower encapsulation inorganic pattern, wherein:
the additional encapsulation inorganic pattern comprises a tip portion that protrudes more than the lower encapsulation inorganic pattern, and
the common inorganic layer is in contact with a lower surface of the additional encapsulation inorganic pattern that defines the tip portion.

18. The method of claim 13, further comprising forming an additional encapsulation inorganic pattern on the lower encapsulation inorganic pattern, wherein:
the side surface of the lower encapsulation inorganic pattern is aligned with a side surface of the additional encapsulation inorganic pattern, and
the common inorganic layer is in contact with the side surface of the lower encapsulation inorganic pattern and the side surface of the additional encapsulation inorganic pattern.

19. The method of claim 13, wherein the forming of the common inorganic layer comprises etching the preliminary common inorganic layer for a set period of time or etching the preliminary common inorganic layer until a specific gas is detected.

20. An electronic device comprising:
a display module generating an image;
a window disposed on the display module; and
a housing disposed under the display module and coupled with the window, the display module comprising:
a pixel definition layer, wherein a light emitting opening is defined in the pixel definition layer;
a barrier wall disposed on the pixel definition layer, wherein a barrier wall opening defined in the barrier wall overlaps the light emitting opening;
a light emitting element disposed in the light emitting opening and the barrier wall opening and comprising an anode, a light emitting pattern, and a cathode that is in contact with the barrier wall;
a lower encapsulation inorganic pattern comprising a first portion disposed in the barrier wall opening and covering the light emitting element, a second portion extending from the first portion in a thickness direction of the pixel definition layer, and a third portion extending from the second portion and spaced apart from an upper surface of the barrier wall when viewed in a cross-section; and
a common inorganic layer covering a side surface of the third portion of the lower encapsulation inorganic pattern.
